(19) United States
(12) Patent Application Publication
(10) Pub. No.: US 2026/0026340 A1
(43) Pub. Date: Jan. 22, 2026

(54) STACKED SEMICONDUCTOR DEVICE

(71) Applicant: SAMSUNG ELECTRONICS CO., LTD., Suwon-si (KR)

(72) Inventors: Jongpil SON, Suwon-si (KR); Kyusik MUN, Suwon-si (KR); Jeongil SEO, Suwon-si (KR); Hong SHIM, Suwon-si (KR); Chisung OH, Suwon-si (KR)

(73) Assignee: SAMSUNG ELECTRONICS CO., LTD., Suwon-si (KR)

(21) Appl. No.: 19/188,656

(22) Filed: Apr. 24, 2025

(30) Foreign Application Priority Data
Jul. 19, 2024 (KR) 10-2024-0095555

(51) Int. Cl. H01L 23/34; H01L 23/00; H01L 23/48; H01L 25/18

(52) U.S. Cl. CPC H01L 23/34; H01L 23/481; H01L 24/08; H01L 25/18; H01L 2224/08146; H01L 2225/06541; H01L 2225/06589; H01L 2924/1431; H01L 2924/1436

(57) ABSTRACT

A stacked semiconductor device includes a base semiconductor die and a plurality of core semiconductor dies that are stacked in a vertical direction, a plurality of temperature sensing circuits included in the plurality of core semiconductor dies, respectively, a conversion circuit included in the base semiconductor die, and a plurality of vertical conductive paths electrically connecting the base semiconductor die and the plurality of core semiconductor dies, through silicon vias provided in the plurality of vertical conductive paths in the vertical direction. The plurality of temperature sensing circuits generate sensing voltages that vary according to operating temperatures, and transfer the sensing voltages to the conversion circuit through a first vertical conductive path among the plurality of vertical conductive paths. The conversion circuit converts the sensing voltages into a temperature code.

### CROSS-REFERENCE TO RELATED APPLICATION

This U.S. non-provisional application claims priority under 35 USC § 119 to Korean Patent Application No. 10-2024-0095555, filed on Jul. 19, 2024, in the Korean Intellectual Property Office (KIPO), the disclosure of which is incorporated by reference herein in its entirety.

### BACKGROUND

### 1. Technical Field

Example embodiments relate to semiconductor integrated circuits, and more particularly to a stacked semiconductor device including a temperature sensing circuit.

### 2. Discussion of the Related Art

There is an ongoing effort to pack more circuits into a limited space for higher capacity, miniaturization, and speed. For example, as hardware becomes faster and software becomes more complex, the memory capacity and the speed required for main memory is increasing. To increase memory capacity, technologies are being used to stack semiconductor dies (or semiconductor chips) inside the package of a memory chip. Stacking a large number of semiconductor dies increases the load on signal paths, such as through silicon vias in stacked semiconductor devices, and complicates temperature distribution in the package.

### SUMMARY

Some example embodiments may provide a stacked semiconductor device, capable of efficiently providing temperature information while minimizing the increase in load on signal paths.

According to example embodiments, a stacked semiconductor device may include: a base semiconductor die comprising a conversion circuit; a plurality of core semiconductor dies that is stacked on the base semiconductor die in a vertical direction and comprises a plurality of temperature sensing circuits, respectively; and a plurality of vertical conductive paths electrically connecting the base semiconductor die and the plurality of core semiconductor dies, through silicon vias provided in the plurality of vertical conductive paths in the vertical direction.

The plurality of temperature sensing circuits is configured to generate sensing voltages that vary according to operating temperatures, and transfer the sensing voltages to the conversion circuit through a first vertical conductive path among the plurality of vertical conductive paths. The conversion circuit is configured to convert the sensing voltages into a temperature code.

According to example embodiments, a stacked semiconductor device includes a base semiconductor die comprising a conversion circuit; a first core semiconductor die on the base semiconductor die in a vertical direction, and the first core semiconductor die comprising a first temperature sensing circuit; a second core semiconductor die on the first core semiconductor die in the vertical direction, the second core semiconductor die comprising a second temperature sensing circuit; and a plurality of vertical conductive paths electrically connecting the base semiconductor die, the first core semiconductor die, and the second core semiconductor die, through silicon vias provided in the plurality of vertical conductive paths in the vertical direction.

The first temperature sensing circuit generates first sensing voltages that vary according to operating temperatures of the first core semiconductor die, and transfers the first sensing voltages to the conversion circuit through a first vertical conductive path among the plurality of vertical conductive paths. The second temperature sensing circuit generates second sensing voltages that vary according to operating temperatures of the second core semiconductor die, and transfer the second sensing voltages to the conversion circuit through the first vertical conductive path. The conversion circuit converts the first sensing voltages and the second sensing voltages to generate a temperature code.

According to example embodiments, a stacked semiconductor device includes a base semiconductor die comprising a conversion circuit; a first core semiconductor die on the base semiconductor die in a vertical direction, and the first core semiconductor die including a first temperature sensing circuit configured to generate first sensing voltages that vary according to operating temperatures of the first core semiconductor die, and a first core reference voltage generator configured to generate a first core reference voltage; a second core semiconductor die on the first core semiconductor die in the vertical direction, the second core semiconductor die including a second temperature sensing circuit configured to generate second sensing voltages that vary according to operating temperatures of the second core semiconductor die, and a second core reference voltage generator configured to generate a second core reference voltage; and a plurality of vertical conductive paths electrically connecting the base semiconductor die, the first core semiconductor die, and the second core semiconductor die, through silicon vias provided in the plurality of vertical conductive paths in the vertical direction.

The first sensing voltages and the second sensing voltages are transferred through a first vertical conductive path among the plurality of vertical conductive paths. The first core reference voltage and the second core reference voltage are transferred through a second vertical conductive path among the plurality of vertical conductive paths.

The stacked semiconductor device according to example embodiments may efficiently provide temperature information of the stacked semiconductor device while optimizing the design margin of the core semiconductor die by disposing the temperature sensing circuit in each core semiconductor die and the conversion circuit common to the plurality of core semiconductor die in the base semiconductor die.

Furthermore, the stacked semiconductor device according to example embodiments may efficiently provide temperature information of the stacked semiconductor device without increasing the load of the signal path by transferring the sensing voltages of the plurality of core semiconductor dies from the plurality of core semiconductor dies to the base semiconductor die using a single vertical conductive path.

### BRIEF DESCRIPTION OF THE DRAWINGS

Example embodiments of the present disclosure will be more clearly understood from the following detailed description taken in conjunction with the accompanying drawings.

FIG. 1 is a diagram illustrating a vertical structure of a stacked semiconductor device according to example embodiments.

FIG. 2 is a diagram illustrating an example embodiment of a temperature sensing circuit and a conversion circuit included in the stacked semiconductor device of FIG. 1.

FIGS. 3 and 4 are circuit diagrams illustrating example embodiments of a temperature sensor included in a stacked semiconductor device according to example embodiments.

FIG. 5 is a timing diagram illustrating operation of a stacked semiconductor device according to example embodiments.

FIG. 6 is a diagram illustrating a vertical structure of a stacked semiconductor device according to example embodiments.

FIG. 7 is a diagram illustrating an example embodiment of a temperature sensing circuit and a conversion circuit included in the stacked semiconductor device of FIG. 6.

FIG. 8 is a diagram illustrating a vertical structure of a stacked semiconductor device according to example embodiments.

FIG. 9 is a diagram illustrating an example embodiment of a temperature sensing circuit and a conversion circuit included in the stacked semiconductor device of FIG. 8.

FIG. 10 is a diagram illustrating one of the sub-sensing intervals of FIG. 5.

FIGS. 11 and 12 are timing diagrams illustrating operation of a stacked semiconductor device according to example embodiments.

FIG. 13 is a block diagram illustrating a memory system according to example embodiments.

FIG. 14 is a perspective diagram illustrating a stacked memory device according to example embodiments.

FIG. 15 is a block diagram illustrating a semiconductor memory device according to example embodiments.

FIG. 16 is a diagram illustrating an example embodiment of a bank array included in a semiconductor memory device according to example embodiments.

FIG. 17 is a diagram illustrating an example embodiment of setting a temperature level in a semiconductor memory device according to example embodiments.

FIG. 18 is a diagram illustrating an example embodiment of register information in a semiconductor memory device according to example embodiments.

FIG. 19 is a block diagram illustrating an example embodiment of a refresh controller included in the semiconductor memory device of FIG. 15.

FIGS. 20, 21 and 22 are timing diagrams illustrating refresh operation of a semiconductor memory device according to example embodiments.

FIG. 23 is a diagram illustrating a memory system according to example embodiments.

FIGS. 24, 25 and 26 are diagrams illustrating stacked semiconductor devices according to example embodiments.

FIG. 27 is a structural diagram illustrating an example embodiment of a semiconductor package including a semiconductor memory device according to example embodiments.

FIG. 28 is a block diagram illustrating a mobile system including a semiconductor memory device according to example embodiments.

### DETAILED DESCRIPTION

Various example embodiments will be described more fully hereinafter with reference to the accompanying drawings, in which some example embodiments are shown. In the drawings, like numerals refer to like elements throughout. The repeated descriptions may be omitted.

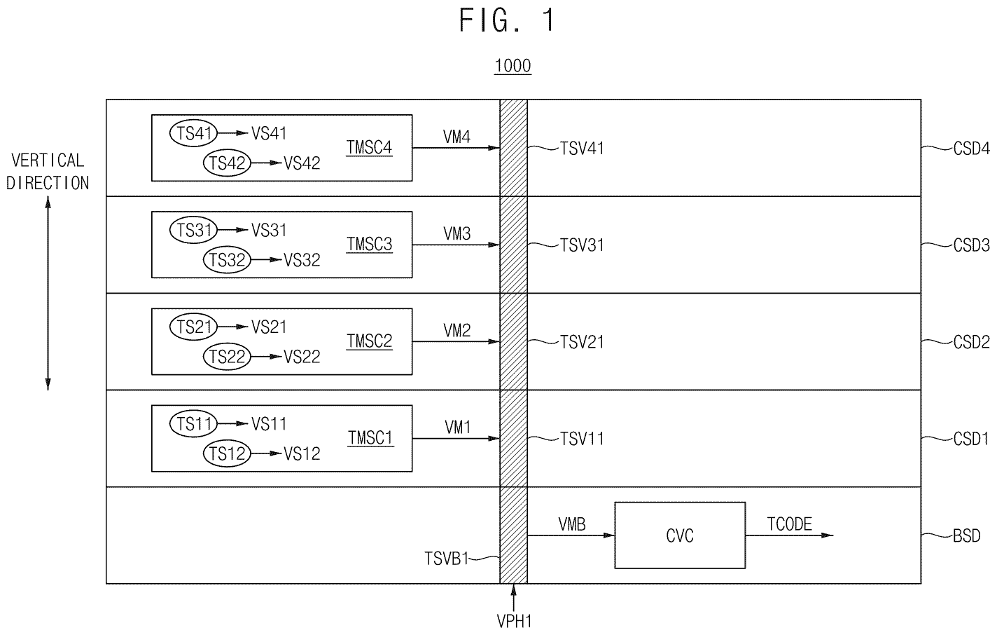

FIG. 1 is a diagram illustrating a vertical structure of a stacked semiconductor device according to example embodiments.

Referring to FIG. 1, a stacked semiconductor device 1000 includes a base semiconductor die BSD, a plurality of core semiconductor dies CSD1, CSD2, CSD3, and CSD4, a plurality of temperature sensing circuits TMSC1, TMSC2, TMSC3, and TMSC4, a conversion circuit CVC, and a plurality of vertical conductive paths including a first vertical conductive path VPH1.

The base semiconductor die BSD and the plurality of core semiconductor dies CSD1, CSD2, CSD3, and CSD4 are stacked in a vertical direction. In FIG. 1, only the first vertical conductive path VPH1 of the plurality of vertical conductive paths is shown for convenience of illustration and description. Also, while FIG. 1 shows four core semiconductor dies CSD1, CSD2, CSD3, and CSD4 stacked above the base semiconductor die BSD for convenience of illustration and description, the number of core semiconductor dies and the position of the base semiconductor die may be varied. In an example embodiment, the plurality of core semiconductor dies CSD1, CSD2, CSD3, and CSD4 may be memory semiconductor dies including memory cells, such as Dynamic Random Access Memory (DRAM) cells, in which case the stacked semiconductor device 1000 may be referred to as a stacked memory device or a semiconductor memory device. The base semiconductor die BSD may be referred to as a buffer die, a buffer semiconductor die, or the like.

The plurality of temperature sensing circuits TMSC1, TMSC2, TMSC3, and TMSC4 are included in the plurality of core semiconductor dies CSD1, CSD2, CSD3, and CSD4, respectively. That is, the first temperature sensing circuit TMSC1 is included in the first core semiconductor die CSD1, the second temperature sensing circuit TMSC2 is included in the second core semiconductor die CSD2, the third temperature sensing circuit TMSC3 is included in the third core semiconductor die CSD3, and the fourth temperature sensing circuit TMSC4 is included in the fourth core semiconductor die CSD4. The conversion circuit CVC is included in the base semiconductor die BSD.

The plurality of vertical conductive paths each include through silicon vias electrically connecting the base semiconductor die BSD and the plurality of core semiconductor dies CSD1, CSD2, CSD3, and CSD4 and disposed in the vertical direction. For example, the first vertical conductive path VPH1 may include through silicon vias TSV11, TSV12, TSV13, and TSV14 that are included in each of the plurality of core semiconductor dies CSD1, CSD2, CSD3, and CSD4 and disposed in the vertical direction. According to example embodiments, the through silicon vias TSV11, TSV12, TSV13, and TSV14 may be electrically connected to each other via micro bumps, contact pads, etc. The through silicon vias TSV11, TSV12, TSV13, and TSV14 may be connected to each other to form a single conductive path extending in the vertical direction.

Each temperature sensing circuit of the plurality of temperature sensing circuits TMSC1, TMSC2, TMSC3, and TMSC4 generates sensing voltages that vary according to the respective operating temperatures and transfers the sensing voltages to the conversion circuit CVC via the first vertical conductive path VPH1, and the conversion circuit CVC converts the sensing voltages to generate a temperature code TCODE.

For example, the first temperature sensing circuit TMSC1 of the first core semiconductor die CSD1 may include temperature sensors TS11 and TS12 configured to generate sensing voltages VS11 and VS12 that vary according to respective operating temperatures, and may transfer a first selection voltage VM1 sequentially including the sensing voltages VS11 and VS12 to the conversion circuit CVC via the first vertical conductive path VPH1. The second temperature sensing circuit TMSC2 of the second core semiconductor die CSD2 may include temperature sensors TS21 and TS22 configured to generate sensing voltages VS21 and VS22 that vary according to respective operating temperatures, and may transfer a second selection voltage VM2 sequentially including the sensing voltages VS21 and VS22 to the conversion circuit CVC through the first vertical conductive path VPH1. The third temperature sensing circuit TMSC3 of the third core semiconductor die CSD3 may include temperature sensors TS31 and TS32 configured to generate sensing voltages VS31 and VS32 that vary according to respective operating temperatures, and may transfer a third selection voltage VM3 sequentially including the sensing voltages VS31 and VS32 to the conversion circuit CVC through the first vertical conductive path VPH1. The fourth temperature sensing circuit TMSC4 of the fourth core semiconductor die CSD4 may include temperature sensors TS41 and TS42 configured to generate sensing voltages VS41 and VS42 that vary according to respective operating temperatures, and may transfer a fourth selection voltage VM4 sequentially including the sensing voltages VS41 and VS42 to the conversion circuit CVC via the first vertical conductive path VPH1. While FIG. 1 illustrates an example where each core semiconductor die includes two temperature sensors for convenience of illustration and description, the number of temperature sensors distributed in each core semiconductor die may be varied.

According to example embodiments, the first selection voltage VM1, the second selection voltage VM2, the third selection voltage VM3, and the fourth selection voltage VM4 may be sequentially transferred to the conversion circuit CVC via the first vertical conductive path VPH1 by a time-division method. The time-division method may refer to a technique for transmitting values or signals sequentially, where each value or signal is transmitted at a specific time interval, ensuring that the transmission of the values or signals does not overlap with each other. This method allows for efficient sharing of a communication medium or pathway by allocating distinct time slots for each signal or value to be transmitted, preventing interference or overlap between transmissions. As will be described below with reference to FIG. 11, the base selection voltage VMB input to the conversion circuit CVC via the first vertical conductive path VPH1 may sequentially include the sensing voltages VS11 and VS12 corresponding to the first core semiconductor die CSD1, the sensing voltages VS21 and VS22 corresponding to the second core semiconductor die CSD2, the sensing voltages VS31 and VS32 corresponding to the third core semiconductor die CSD3, and the sensing voltages VS41 and VS42 corresponding to the fourth core semiconductor die CSD4. The conversion circuit CVC may sequentially convert these received sensing voltages VS11, VS12, VS21, VS22, VS31, VS32, VS41, and VS42 into corresponding digital values of the temperature code TCODE by a time-division method.

As such, the stacked semiconductor device 1000 according to example embodiments may efficiently provide temperature information of the stacked semiconductor device 1000 while optimizing the design margin of the core semiconductor die by disposing a temperature sensing circuit in each core semiconductor die and disposing a conversion circuit CVC, which is common to the plurality of core semiconductor dies CSD1, CSD2, CSD3, and CSD4, in the base semiconductor die BSD.

Further, the stacked semiconductor device 1000 according to example embodiments may efficiently provide temperature information of the stacked semiconductor device 1000 without increasing the load on the signal path by transferring the sensing voltages of the plurality of core semiconductor dies CSD1, CSD2, CSD3, and CSD4 from the plurality of core semiconductor dies CSD1, CSD2, CSD3, and CSD4 to the base semiconductor die BSD using one vertical conductive path VPH1.

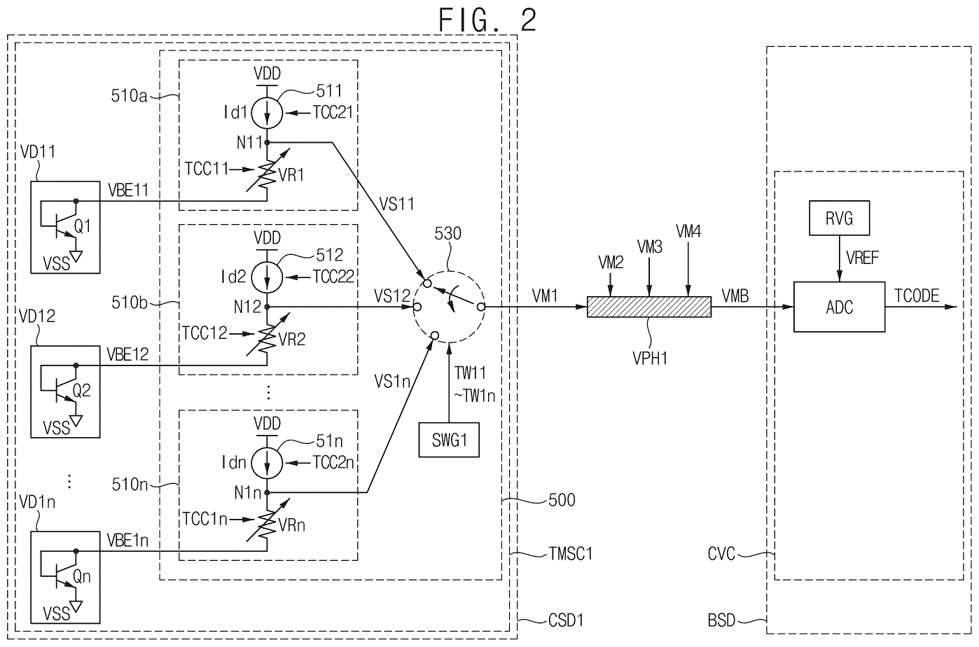

FIG. 2 is a diagram illustrating an example embodiment of a temperature sensing circuit and a conversion circuit included in the stacked semiconductor device of FIG. 1. For convenience of illustration and description, example embodiments will be described with reference to FIG. 2 centered on the configuration of a first core semiconductor die CSD1, but it will be understood that other core semiconductor dies CSD2, CSD3 and CSD4 may have the same or similar configuration as the first core semiconductor die CSD1.

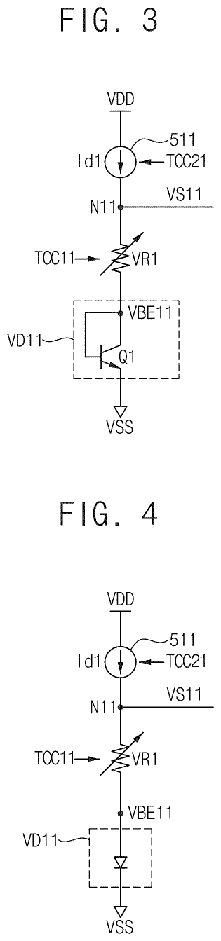

FIG. 2 illustrates an example embodiment in which a plurality of voltage devices VD1, VD2, . . . , VDn are implemented as bipolar junction transistors Q1, Q2, . . . , Qn configured to provide temperature-dependent voltage values. As will be described below with reference to FIGS. 3 and 4, the voltage device may correspond to a portion of a temperature sensor.

Referring to FIG. 2, each of the bipolar junction transistors Q1, Q2, . . . , Qn may include an emitter connected to a ground voltage VSS, a collector connected to the time-division detector 500 and providing a temperature voltage corresponding to one of the temperature voltages VBE11, VBE12, . . . , VBE1n, and a base connected to the collector.

Since the collector and the base are connected to each other in each of the bipolar junction transistors Q1, Q2, . . . , Qn, the collector of each of the bipolar junction transistors Q1, Q2, . . . , Qn may provide a Complementary To Absolute Temperature (CTAT) voltage that decreases as each of the ambient temperatures (i.e., the operating temperatures) increases at the collector of each of the bipolar junction transistors Q1, Q2, . . . , Qn with the corresponding temperature voltage.

The time-division sensing circuit 500 may include a plurality of sensing units 510a, 510b, . . . , 510n, a multiplexer 530, and a first core timing controller SWG1. The sensing units 510a, 510b, . . . , 510n may be also referred to as voltage adjustment circuits. The conversion circuit CVC may include a base reference voltage generator RVG and an analog-to-digital converter ADC.

The plurality of sensing units 510a, 510b, . . . , 510n may receive the temperature voltages VBE11, VBE12, . . . , VBE1n, and may output corresponding sensing voltages VS11, VS12, . . . , VS1n, and provide the sensing voltages VS11, VS12, . . . , VS1n to the multiplexer 530.

The sensing unit 510a may include a current source 511 and a variable resistor VR1. The current source 511 may be connected between the power supply voltage VDD and the first node N11, and may provide a reference current Id1 to the first node N11. The variable resistor VR1 may have a first terminal connected to the first node N11 and a second terminal receiving the temperature voltage VBE11. The sensing unit 510a may provide a voltage corresponding to the sum of the temperature voltage VBE11 and the product of the reference current Id1 and the resistance value of the variable resistor VR1 to the multiplexer 530 as the sensing voltage VS11.

The sensing unit 510b may include a current source 512 and a variable resistor VR2. The current source 512 may be connected between the power supply voltage VDD and the first node N12, and may provide a reference current Id2 to the first node N12. The variable resistor VR2 may have a first terminal connected to the first node N12 and a second terminal receiving the temperature voltage VBE12. The sensing unit 510b may provide a voltage corresponding to the sum of the temperature voltage VBE12 and the product of the reference current Id2 and the resistance value of the variable resistor VR2 to the multiplexer 530 as the sensing voltage VS12.

The sensing unit 510n may include a current source 51n and a variable resistor VRn. The current source 51n may be connected between a power supply voltage VDD and the first node N1n, and may provide a reference current Idn to the first node N1n. The variable resistor VRn may have a first terminal connected to the first node N1n and a second terminal receiving the temperature voltage VBE1n. The sensing unit 510n may provide a voltage corresponding to the sum of the temperature voltage VBE1n and the product of the reference current Idn and the resistance value of the variable resistor VRn to the multiplexer 530 as the sensing voltage VS1n.

The multiplexer 530 may receive the first sensing voltages VS11, VS12, . . . , VS1n corresponding to the first core semiconductor die CSD1, and may sequentially select the first sensing voltages VS11, VS12, . . . , VS1n based on first output timing control signals TW11, TW12, TW13, . . . , TW1n to provide a first selection voltage VM1. The first selection voltage VM1 may be transferred to the conversion circuit CVC via the first vertical conductive path VPH1.

In this way, the first selection voltage VM1 generated by the first core semiconductor die CSD1, the second selection voltage VM2 generated by the second core semiconductor die CSD2, the third selection voltage VM3 generated by the third core semiconductor die CSD3, and the fourth selection voltage VM4 generated by the fourth core semiconductor die CSD4 may all be transferred to the conversion circuit CVC by a time-division method through the first vertical conductive path VPH1. In other words, the base selection voltage VMB input to the conversion circuit CVC may sequentially include the first selection voltage VM1, the second selection voltage VM2, the third selection voltage VM3, and the fourth selection voltage VM4.

The base reference voltage generator RVG may generate a temperature-independent base reference voltage VREF and provide the base reference voltage VREF to the analog-to-digital converter ADC. In an example embodiment, the base reference voltage generator RVG may be implemented as a band-gap reference circuit.

The analog-to-digital converter ADC may generate digital values of the temperature code TCODE by comparing the base reference voltage VREF and the sensing voltages corresponding to the plurality of core semiconductor dies included in the base selection voltage VMB.

According to example embodiments, each of first trimming control codes TCC11, TCC12, . . . , TCC1n may be provided to each of the variable resistors VR1, VR2, . . . , VRn and each of second trimming control codes TCC21, TCC22, . . . , TCC2n may be provided to each of the current sources 511, 512, . . . , 51n.

The first trimming control codes TCC11, TCC12, . . . , TCC1n may compensate for errors between resistance values due to process deviations of the variable resistors VR1, VR2, . . . , VRn, and ensure that the sensing voltages VS11, VS12, . . . , VS1n have voltage values that are inversely proportional to temperature.

The second trimming control codes TCC21, TCC22, . . . , TCC2n may compensate for errors between the reference currents Id1, Id2, . . . , Idn due to process deviations of the current sources 511, 512, . . . , 51n, and may ensure that the sensing voltages VS11, VS12, . . . , VS1n have voltage values that are inversely proportional to temperature.

FIGS. 3 and 4 are circuit diagrams illustrating example embodiments of a temperature sensor included in a stacked semiconductor device according to example embodiments. For convenience of illustration and description, one temperature sensor is shown in each of FIGS. 3 and 4, and a plurality of temperature sensors included in the stacked semiconductor device may all have the same or similar configuration.

Referring to FIGS. 3 and 4, the temperature sensor may include a current source 511, a variable resistor VR1, and a voltage device VD11. In an example embodiment, the voltage device VD11 may be implemented as a bipolar junction transistor Q1, as shown in FIG. 3. In another example embodiment, the voltage device VD11 may be implemented as a diode D1, as shown in FIG. 4.

The voltage device VD11 may provide a temperature voltage VBE11 as a CTAT Complementary To Absolute Temperature (CTAT) voltage that decreases as the respective ambient temperature (i.e., operating temperature) increases. The current source 511 may be connected between the power supply voltage VDD and the first node N11, and may provide a reference current Id1 to the first node N11. The variable resistor VR1 may have a first terminal connected to the first node N11 and a second terminal receiving the temperature voltage VBE11. The sensing unit 510a of FIG. 2 may provide a voltage corresponding to the sum of the temperature voltage VBE11 and the product of the reference current Id1 and the resistance value of the variable resistor VR1 as the sensing voltage VS11.

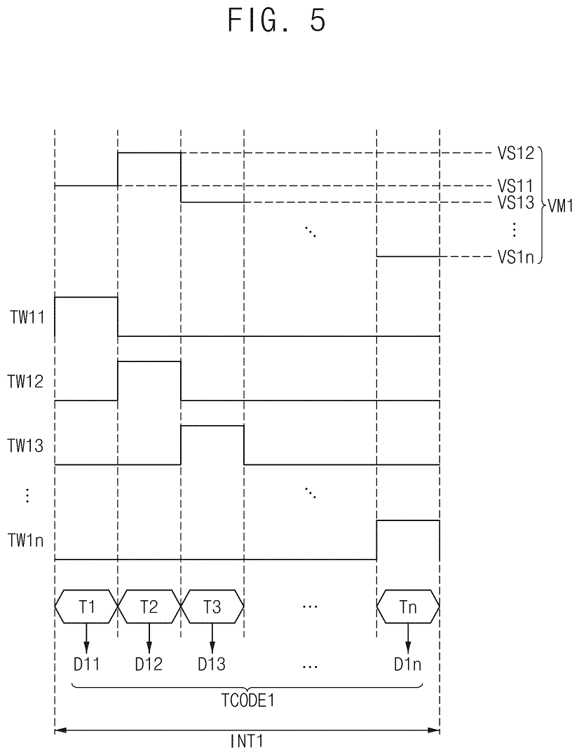

FIG. 5 is a timing diagram illustrating operation of a stacked semiconductor device according to example embodiments.

Referring to FIGS. 2 and 5, the first core timing controller SWG1 may divide the first sensing interval INT1 into a plurality of sub-sensing intervals T1, T2, T3, . . . , Tn, activate each of the first output timing control signals TW11, TW12, TW13, . . . , TW1n in each of the plurality of sub-sensing intervals T1, T2, T3, . . . , Tn, and provide the first output timing control signals TW1 through TWn to the multiplexer 530.

The multiplexer 530 may select the first sensing voltages VS11, VS12, . . . , VS1n one by one during the sub-sensing intervals T1, T2, T3, . . . , Tn in response to the first output timing control signals TW11, TW12, TW13, . . . , TW1n that are sequentially activated, and provide the first sensing voltages VS11, VS12, . . . , VS1n to the first vertical conductive path VPH1 as the first selection voltage VM. The conversion circuit CVC of the base semiconductor die BSD may convert the first sensing voltages VS11, VS12, . . . , VS1n to generate a first temperature code TCODE1 including digital values D11, D12, . . . , D1n corresponding to the first sensing voltages VS11, VS12, . . . , VS1n, respectively.

Configuration and method for providing temperature information of a first core semiconductor die CSD1 has been described referring to FIGS. 2 through 5, but it will be understood that temperature information of the second core semiconductor die CSD2, the third core semiconductor die CSD3, and the fourth core semiconductor die CSD4 may be provided in the same way. The sensing voltages of the first core semiconductor die CSD1, the second core semiconductor die CSD2, the third core semiconductor die CSD3, and the fourth core semiconductor die CSD4 may be sequentially transferred to the conversion circuit CVC via the first vertical conductive path VPH1 by a time-division method.

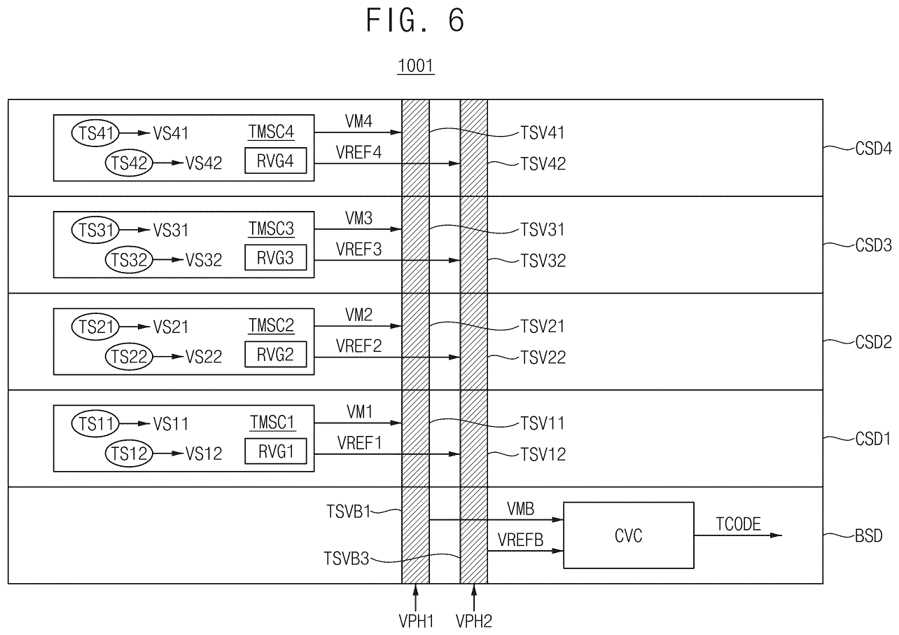

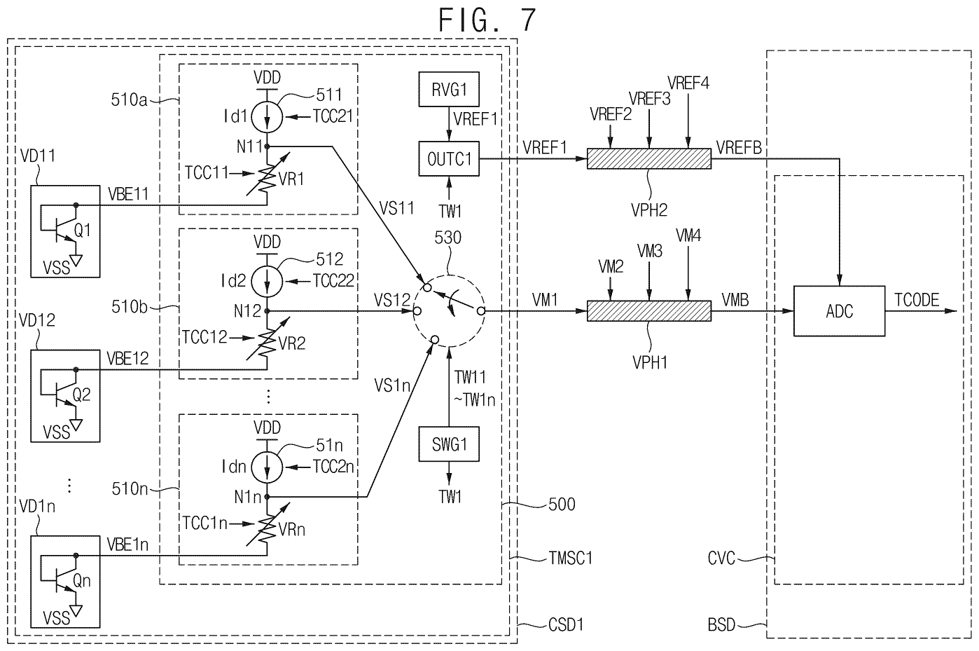

FIG. 6 is a diagram illustrating a vertical structure of a stacked semiconductor device according to example embodiments, and FIG. 7 is a diagram illustrating an example embodiment of a temperature sensing circuit and a conversion circuit included in the stacked semiconductor device of FIG. 6.

Referring to FIGS. 6 and 7, a stacked semiconductor device 1001 includes a base semiconductor die BSD, a plurality of core semiconductor dies CSD1, CSD2, CSD3, and CSD4, a plurality of temperature sensing circuits TMSC1, TMSC2, TMSC3, and TMSC4, a conversion circuit CVC, and a plurality of vertical conductive paths. In FIGS. 6 and 7, only a first vertical conductive path VPH1 and a second vertical conductive path VPH2 of the plurality of vertical conductive paths are shown for convenience of illustration and description. Descriptions that are redundant with FIGS. 1 through 5 are hereinafter omitted.

Compared to the stacked semiconductor device 1000 of FIGS. 1 and 2, in the stacked semiconductor device 1001 of FIGS. 6 and 7, each temperature sensing circuit may further include a core reference voltage generator that generates a core reference voltage having a constant voltage level independent of temperature. In other words, the first temperature sensing circuit TMSC1 of the first core semiconductor die CSD1 includes a first core reference voltage generator RVG1 generating a first core reference voltage VREF1, the first temperature sensing circuit TMSC2 of the second core semiconductor die CSD2 includes a second core reference voltage generator RVG2 generating a second core reference voltage VREF2, the third temperature sensing circuit TMSC3 of the third core semiconductor die CSD3 may include a third core reference voltage generator RVG3 generating a third core reference voltage VREF3, and the fourth temperature sensing circuit TMSC4 of the fourth core semiconductor die CSD4 may include a fourth core reference voltage generator RVG4 generating a fourth core reference voltage VREF4.

The plurality of temperature sensing circuits TMSC1, TMSC2, TMSC3, and TMSC4 may sequentially transfer the core reference voltages VREF1 through VREF4 corresponding to the plurality of core semiconductor dies CSD1, CSD2, CSD3, and CSD4 to the conversion circuit CVC of the base semiconductor die BSD via the second vertical conductive path VPH2 by a time-division method during the plurality of sensing intervals.

As shown in FIG. 7, the first temperature sensing circuit TMSC1 of the first core semiconductor die CSD1 may include a first output circuit OUTC1 that controls the timing of transferring the first core reference voltage VREF1 to the second vertical conductive path VPH2. The first output circuit OUTC1 may output the first core reference voltage VREF1 to the second vertical conductive path VPH2 during the first sensing interval INT1 based on the first core timing control signal TW1 activated during the first sensing interval INT1 of FIG. 5. The first core timing control signal TW1 may be generated by the first core timing controller SWG1.

In this way, the first reference voltage VREF1 generated by the first core semiconductor die CSD1, the second reference voltage VREF2 generated by the second core semiconductor die CSD2, the third reference voltage VREF3 generated by the third core semiconductor die CSD3, and the fourth reference voltage VREF4 generated by the fourth core semiconductor die CSD4 may all be transferred to the conversion circuit CVC by a time-division method through the second vertical conductive path VPH2. In other words, the base reference voltage VREFB input to the conversion circuit CVC may sequentially include the first reference voltage VREF1, the second reference voltage VREF2, the third reference voltage VREF3, and the fourth reference voltage VREF4.

The conversion circuit CVC may include the analog-to-digital converter ADC that compares each of the core reference voltages of the plurality of core reference voltages VREF1 through VREF4 and the sensing voltages corresponding to the respective core semiconductor die to generate a digital value of a temperature code TCODE.

As such, the stacked semiconductor device 1001 of FIGS. 6 and 7 may convert the sensing voltages corresponding to the respective core semiconductor die into digital values by utilizing the respective core reference voltages corresponding to the respective core semiconductor die. Thus, the sensing voltages and the reference voltages may be correlated for each core semiconductor die to offset process deviations, voltage deviations, etc. of the core semiconductor die to provide more accurate temperature information.

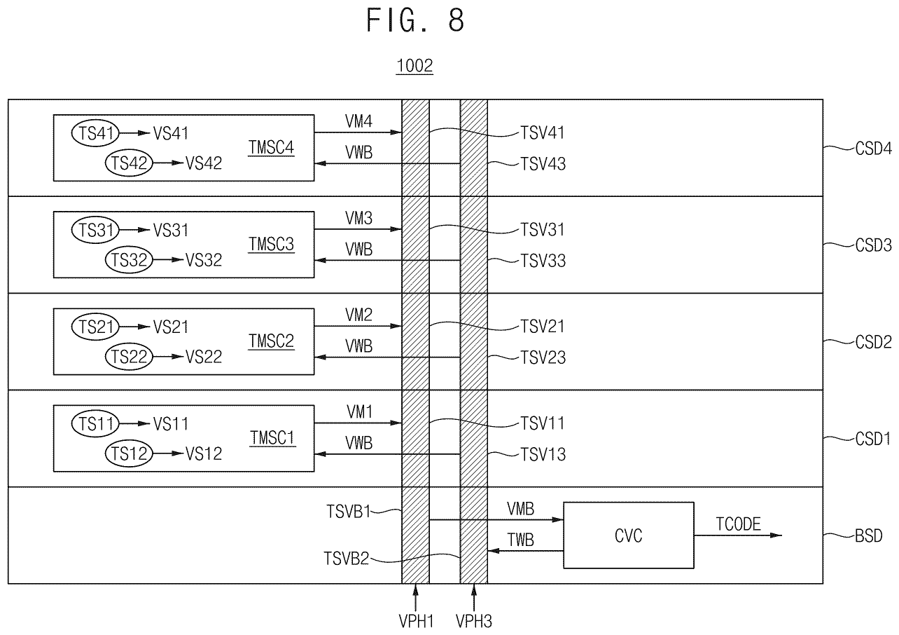

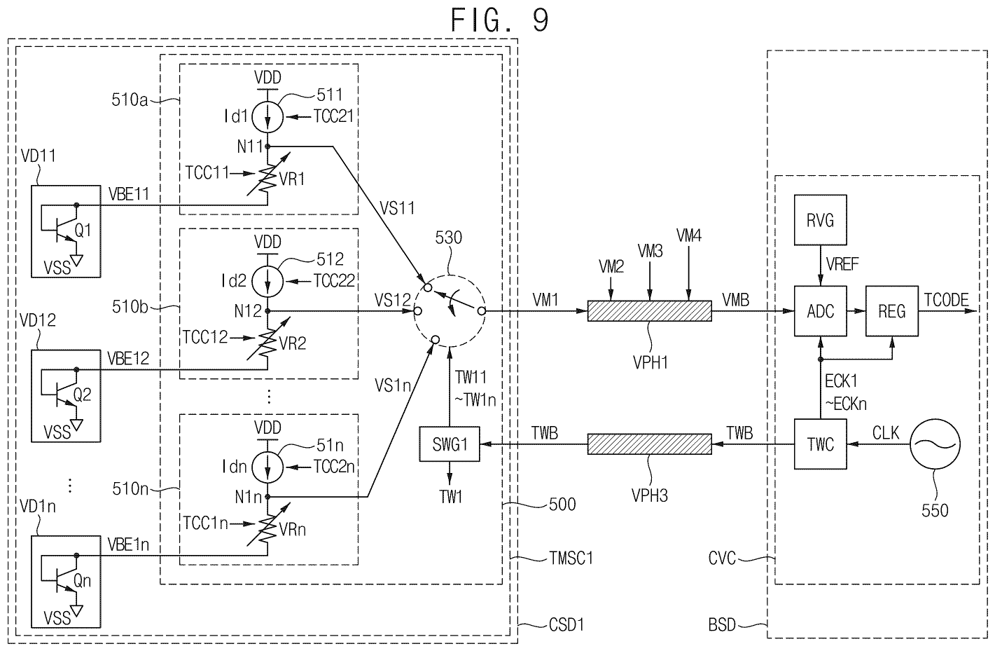

FIG. 8 is a diagram illustrating a vertical structure of a stacked semiconductor device according to example embodiments, and FIG. 9 is a diagram illustrating an example embodiment of a temperature sensing circuit and a conversion circuit included in the stacked semiconductor device of FIG. 8.

Referring to FIGS. 8 and 9, a stacked semiconductor device 1002 includes a base semiconductor die BSD, a plurality of core semiconductor dies CSD1, CSD2, CSD3, and CSD4, a plurality of temperature sensing circuits TMSC1, TMSC2, TMSC3, and TMSC4, a conversion circuit CVC, and a plurality of vertical conductive paths. In FIGS. 8 and 9, only a first vertical conductive path VPH1 and a third vertical conductive path VPH3 of the plurality of vertical conductive paths are shown for convenience of illustration and description. Description that is redundant with FIGS. 1 through 7 is hereinafter omitted.

Compared to the stacked semiconductor device 1000 of FIGS. 1 and 2, in the stacked semiconductor device 1002 of FIGS. 8 and 9, the conversion circuit CVC of the base semiconductor die BSD may further include an oscillator 550, a base timing controller TWC, and a register REG.

The oscillator 550 may generate a clock signal CLK and provide the clock signal CLK to the base timing controller TWC.

The base timing controller TWC may generate a base timing control signal TWB representing a plurality of sensing intervals based on the clock signal CLK and may transfer the base timing control signal TWB to the plurality of temperature sensing circuits TMSC1, TMSC2, TMSC3, and TMSC4 respectively included in the plurality of core semiconductor dies CSD1, CSD2, CSD3, and CSD4. In an example embodiment, as shown in FIGS. 8 and 9, the conversion circuit CVC may transfer the base timing control signal TWB to the plurality of temperature sensing circuits TMSC1, TMSC2, TMSC3, and TMSC4 via the third vertical conductive path VPH3 of the plurality of vertical conductive paths.

As described above with reference to FIGS. 1 and 2, each temperature sensing circuit included in each core semiconductor die may include a respective core timing controller. Each core timing controller may generate output timing control signals that are sequentially activated during each sensing interval of the plurality of sensing intervals based on the base timing control signal TWB.

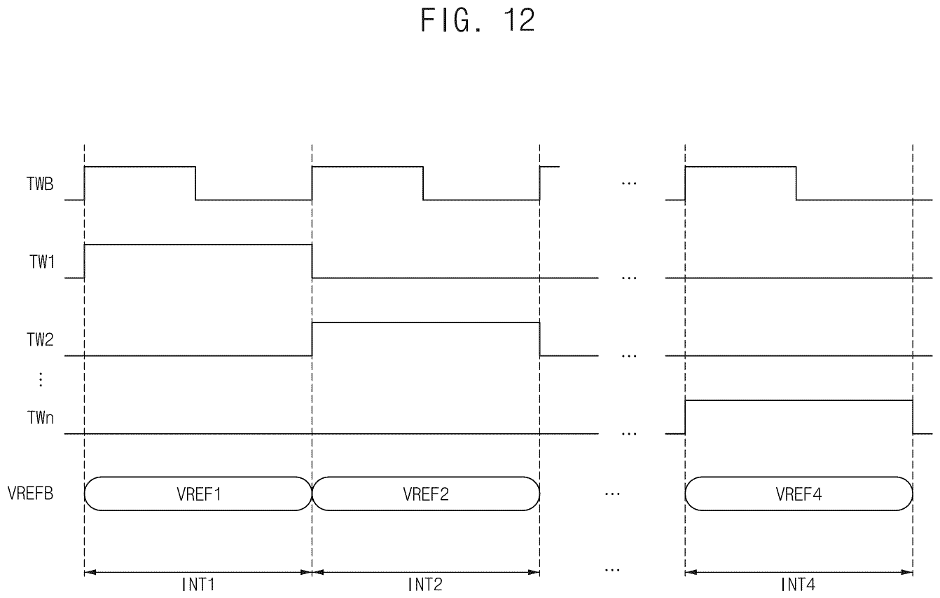

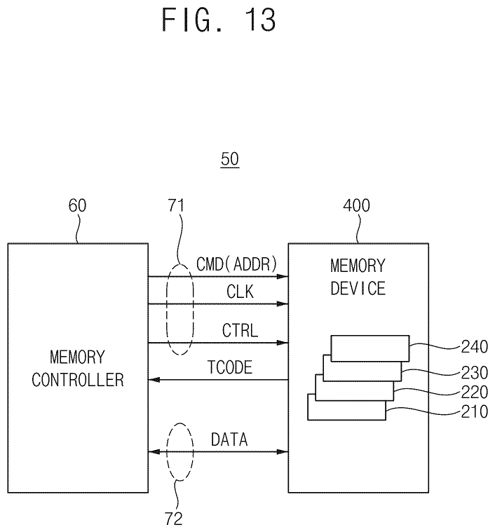

As will be described below with reference to FIG. 12, the first core timing controller SWG1 included in the first temperature sensing circuit TMSC1 of the first core semiconductor die CSD1 may generate a first core timing control signal TW1 and first output timing control signals TW11, TW12, TW13, . . . , TW1n that are activated during the first sensing interval INT1 of the plurality of sensing intervals INT1, INT2, . . . , INT4. The second core timing controller SWG2 included in the second temperature sensing circuit TMSC2 of the second core semiconductor die CSD2 may generate a second core timing control signal TW2 and the second output timing control signals TW21, TW22, TW23, . . . , TW2n that are activated during the second sensing interval INT2 of the plurality of sensing intervals. In the same way, the third core timing controller SWG3 included in the third temperature sensing circuit TMSC3 of the third core semiconductor die CSD3 may generate a third core timing control signal TW3 and the third output timing control signals TW31, TW32, TW33, . . . , TW3n that are activated during the third sensing interval INT3, and the fourth core timing controller SWG4 included in the fourth temperature sensing circuit TMSC4 of the fourth core semiconductor die CSD4 may generate a fourth core timing control signal TW4 and the fourth output timing control signals TW41, TW42, TW43, . . . , TW4n that are activated during the fourth sensing interval INT4.

As a result, each temperature sensing circuit included in each core semiconductor die may transfer sensing voltages corresponding to each core semiconductor die during each sensing interval by a time-division method sequentially through the first vertical conductive path VPH1 to the conversion circuit of the base semiconductor die BSD based on the respective output timing control signals.

Meanwhile, the base timing controller TWC may provide latch timing control signals ECK1˜ECKn to the register REG based on the clock signal CLK. The register REG may sequentially store digital values of the temperature code TCODE based on the latch timing control signals ECK1 through ECKn.

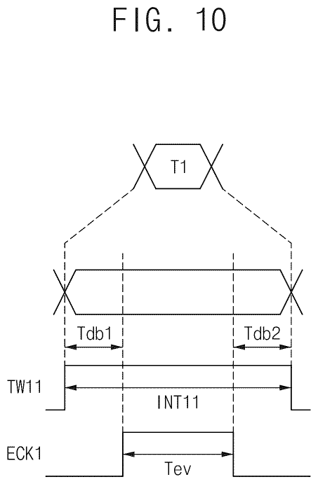

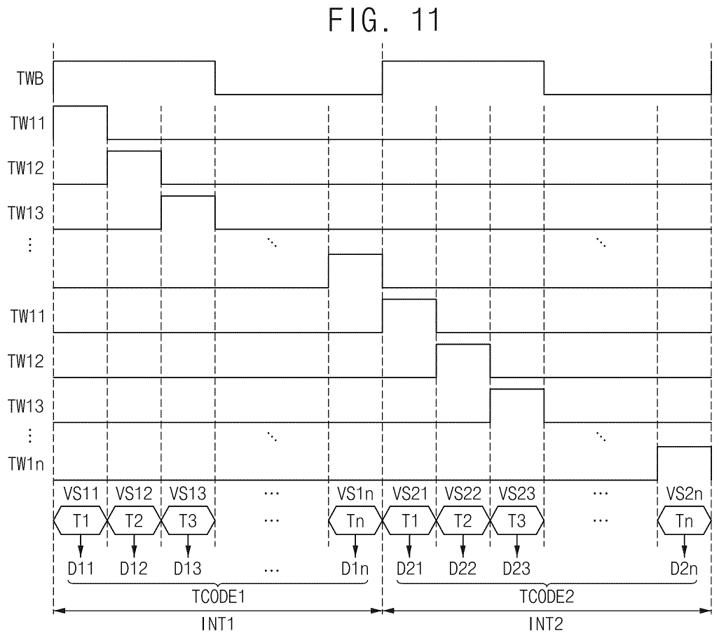

Each of the core timing control signal TW1, TW2, . . . , TWn may have a first activation interval, and each of the latch timing control signals Eck1 through Eckn may have a second activation interval smaller than the first activation interval as will be described below with reference to FIG. 10.

FIG. 10 is a diagram illustrating one of the sub-sensing intervals of FIG. 5.

FIG. 10 illustrates sub-sensing interval T1 of the sub-sensing intervals T1, T2, T3, . . . , Tn of the first sensing interval INT1 in more detail, although the configuration of each of the sub-sensing intervals T2, T3, . . . , Tn may be substantially the same as the configuration of sub-sensing interval T1.

Referring to FIG. 10, the sub-sensing section T1 may correspond to a first activation interval INT11 of the output timing control signal TW11, and the latch timing control signal ECK1 corresponding to the output timing control signal TW11 may have a second activation interval Tev smaller than the first activation interval INT11.

The base timing controller TWC of FIG. 9 may determine the second activation interval Tev of the latch timing control signal ECK1 by excluding the debouncing intervals Tdb1 and Tdb2 from the first activation interval INT11 such that the analog-to-digital converter ADC may operate stably.

The analog-to-digital converter ADC may latch the sensing voltage VS11 included in the base selection voltage VMB in response to an edge of the latch timing control signal ECK1 to generate a digital value corresponding to the sensing voltage VS11.

FIGS. 11 and 12 are timing diagrams illustrating operation of a stacked semiconductor device according to example embodiments.

Referring to FIGS. 6 through 9 and 11, the core timing controller included in each temperature sensing circuit may generate output timing control signals that are sequentially activated during each sensing interval of the plurality of sensing intervals based on the base timing control signal TWB.

As shown in FIG. 11, the first core timing controller SWG1 included in the first temperature sensing circuit TMSC1 of the first core semiconductor die CDS1 may generate a first set of output timing control signals TW11, TW12, TW13, . . . , TW1n that are sequentially activated during the first sensing interval INT1 based on the base timing control signal TWB. The second core timing controller included in the first temperature sensing circuit TMSC2 of the second core semiconductor die CDS2 may generate the second output timing control signals TW21˜TW2n that are sequentially activated during the second sensing interval INT2 based on the base timing control signal TWB. The core timing controllers, each included in the plurality of core semiconductor dies to be sequentially enabled in different sensing intervals, may include a ring counter.

The multiplexer 530 of the first core semiconductor die CSD1 may transfer the first sensing voltages VS11 through VS1n corresponding to the first core semiconductor die CSD1 to the conversion circuit CVC via the first vertical conductive path VPH1 sequentially by a time-division method during the first sensing interval INT1 based on the first output timing control signals TW11, TW12, TW13, . . . , TW1n that are sequentially activated during the first sensing interval INT1. The multiplexer 530 of the second core semiconductor die CSD2 may transfer the second sensing voltages VS21 through VS2n corresponding to the second core semiconductor die CSD2 during the second sensing interval INT2 to the conversion circuit CVC through the first vertical conductive path VPH1 sequentially by a time-division method based on the second output timing control signals TW21 through TW2n that are sequentially activated during the second sensing interval INT2.

The analog-to-digital converter ADC may convert the first sensing voltages VS11 through VS1n to corresponding digital values D11 through Din during the first sensing interval INT1 to generate a first temperature code TCODE1, and may convert the second sensing voltages VS21 through VS2n to corresponding digital values D21 through D2n during the second sensing interval INT2 to generate a second temperature code TCODE2.

Referring to FIGS. 6 to 9 and 12, the plurality of core timing controllers included in each of the plurality of core semiconductor dies may generate a plurality of core timing control signals TW1 through TW4 that are sequentially activated in each of the sensing intervals INT1 through INT4 based on a base timing control signal TWB transferred from the base semiconductor die BSD.

In other words, the first core timing controller SWG1 included in the first temperature sensing circuit TMSC1 of the first core semiconductor die CSD1 may generate the first core timing control signal TW1 that is activated during the first sensing interval INT1, the second core timing controller included in the second temperature sensing circuit TMSC2 of the second core semiconductor die CSD2 may generate the second core timing control signal TW2 that is activated during the second sensing interval INT2. The third core timing controller included in the third temperature sensing circuit TMSC3 of the third core semiconductor die CSD3 may generate the third core timing control signal TW3 that is activated during the third sensing interval INT3. The fourth core timing controller included in the fourth temperature sensing circuit TMSC4 of the fourth core semiconductor die CSD4 may generate the fourth core timing control signal TW4 that is activated during the fourth sensing interval INT4.

The plurality of temperature sensing circuits TMSC1, TMSC2, TMSC3, and TMSC4 may transfer, based on the plurality of core timing control signals TW1 through TW4 corresponding to the plurality of core semiconductor dies CSD1, CSD2, CSD3, and CSD4, the plurality of core reference voltages VREF1 through VREF4 corresponding to the plurality of core semiconductor dies CSD1, CSD2, CSD3, and CSD4 to the conversion circuit CVC of the base semiconductor die BSD through the second vertical conductive path VPH2 sequentially by a time-division method.

In other words, the first output circuit OUTC1 of the first temperature sensing circuit TMSC1 may transfer the first core reference voltage VREF1 during the first sensing interval INT1 to the conversion circuit CVC through the second vertical conductive path VPH2 based on the first core timing control signal TW1 that is activated during the first sensing interval INT1. The second output circuit of the second temperature sensing circuit TMSC2 may transfer the second core reference voltage VREF2 to the conversion circuit CVC via the second vertical conductive path VPH2 during the second sensing interval INT2 based on the second core timing control signal TW2 that is activated during the second sensing interval INT2. The third output circuit of the third temperature sensing circuit TMSC3 may transfer the third core reference voltage VREF3 to the conversion circuit CVC via the second vertical conductive path VPH2 during the third sensing interval INT3 based on the third core timing control signal TW3 that is activated during the third sensing interval INT3. The fourth output circuit of the fourth temperature sensing circuit TMSC4 may transfer the fourth core reference voltage VREF4 to the conversion circuit CVC via the second vertical conductive path VPH2 during the fourth sensing interval INT4 based on the fourth core timing control signal TW4 that is activated during the fourth sensing interval INT4.

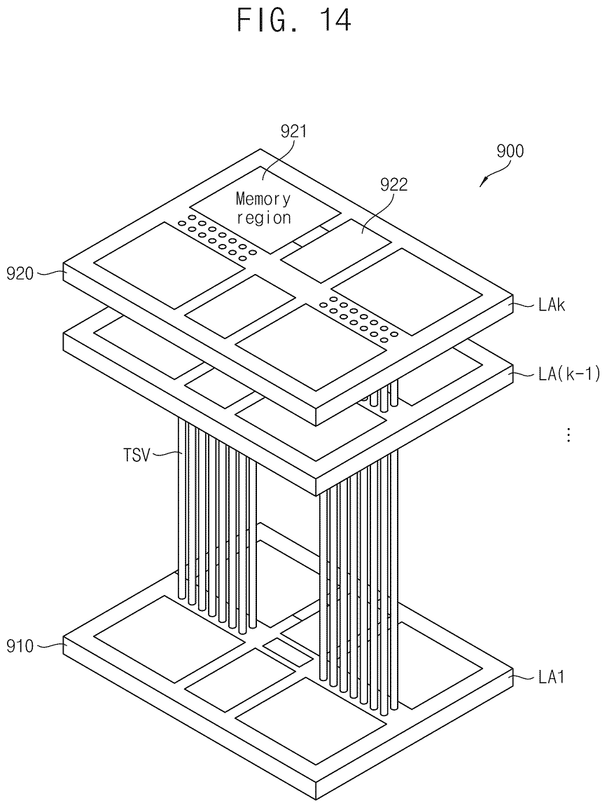

FIG. 13 is a block diagram illustrating a memory system according to example embodiments.

Referring to FIG. 13, a memory system 50 includes a memory controller 60 and a semiconductor memory device 400. The memory controller 60 and the semiconductor memory device 400 include interfaces for communicating with each other.

The interfaces may be connected via a control bus 71 for transferring commands CMD, access addresses ADDR, clock signals CLK, control signals CTRL, and the like, and a data bus 72 for transferring data.

Depending on the type of semiconductor memory device, the command CMD may be considered to include the access address ADDR. The memory controller 60 generates commands CMD to control the semiconductor memory device 400, and data may be written to the semiconductor memory device 400 or data may be read from the semiconductor memory device 400 under the control of the memory controller 60.

The semiconductor memory device 400 may be implemented in the form of a semiconductor package in which a plurality of semiconductor dies 210, 220, 230, 240 are stacked, as described with reference to FIGS. 1 through 12. The semiconductor memory device 400 may provide a temperature code TCODE including temperature information of each semiconductor die to the memory controller 60 as described above, and the memory controller 60 may control refresh operation, bandwidth, etc. of the semiconductor memory device 400 based on the temperature code TCODE.

FIG. 14 is a perspective diagram illustrating a stacked memory device according to example embodiments.

Referring to FIG. 14, a semiconductor memory device 900 may include a plurality of semiconductor dies or semiconductor layers LA1, . . . , LA(k−1), and LAK, where k is a natural number greater than or equal to three. The lowermost semiconductor layer LA1 may be a master layer and the remaining semiconductor layers LA2, . . . , LA(k−1), and LAk may be slave layers. The master layer may correspond to the base semiconductor die described above and the slave layers may correspond to the core semiconductor die described above.

The semiconductor layers LA1, . . . , LA(k−1), and LAk transmit and receive signals to and from each other via the through silicon vias TSV, and the master layer LA1 may communicate with an external memory controller via the chip input/output pad portion. The chip I/O pad portion may be formed on the underside of the master layer LA1 or may be formed on the base substrate.

The first semiconductor layer 910 and the second semiconductor layer 920 each have various peripheral circuits 922 for driving the memory cell array region 921. For example, the peripheral circuits 922 may include a row driver for driving a wordline of each memory cell array region 921, a column driver for driving a bitline of each memory region, a data input and output section for controlling the input and output of data, a command buffer for receiving and buffering commands CMD from the outside, an address buffer for receiving and buffering addresses from the outside, and the like.

The first semiconductor layer 910 may further include control logic. The control logic may control access to the memory region 921 based on command and address signals provided from the memory controller, and may generate control signals for accessing the memory region 921.

According to example embodiments, the semiconductor layers LA2, . . . , LA(k−1), and LAk corresponding to the slave layer may each include the temperature sensing circuits described above, and the first semiconductor layer LA1 corresponding to the master layer may include the conversion circuit described above.

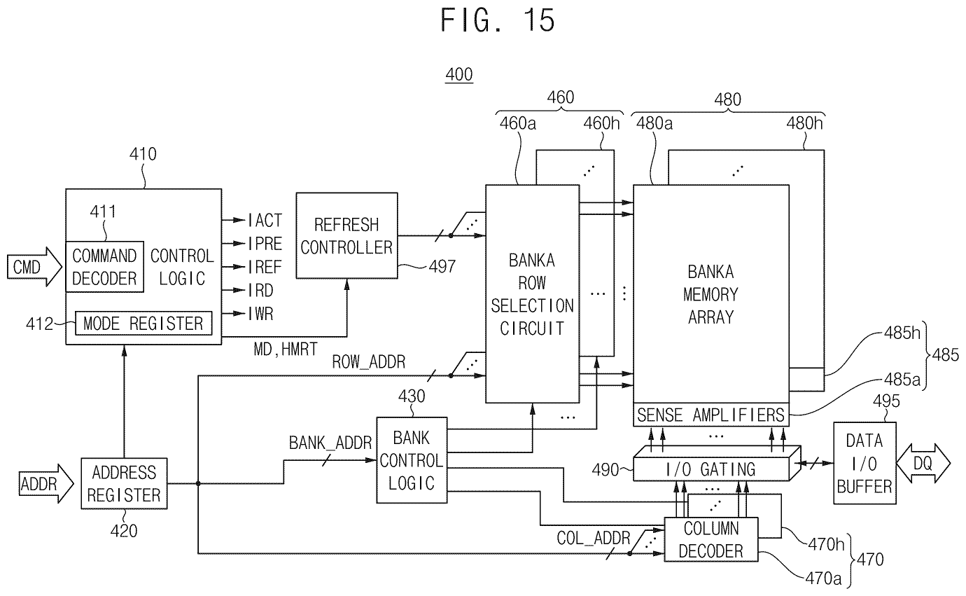

FIG. 15 is a block diagram illustrating a semiconductor memory device according to example embodiments.

Referring to FIG. 15, a semiconductor memory device 400 may include a command control logic 410, an address register 420, a bank control logic 430, a row selection circuit 460 (or row decoder), a column decoder 470, a memory cell array 480, a sense amplifier unit 485, an input-output (I/O) gating circuit 490, a data input-output (I/O) buffer 495, and a refresh controller 497.

The memory cell array 480 may include a plurality of bank arrays 480a, . . . , 480h. The row selection circuit 460 may include a plurality of bank row selection circuits 460a, . . . , 460h respectively coupled to the bank arrays 480a, . . . , 480h. The column decoder 470 may include a plurality of bank column decoders 470a, . . . , 470h respectively coupled to the bank arrays 480a, . . . , 480h. The sense amplifier unit 485 may include a plurality of bank sense amplifiers 485a, . . . , 485h respectively coupled to the bank arrays 480a, . . . , 480h.

The address register 420 may receive an address ADDR including a bank address BANK_ADDR, a row address ROW_ADDR, and a column address COL_ADDR from the memory controller 50. The address register 420 may provide the received bank address BANK_ADDR to the bank control logic 430, may provide the received row address ROW_ADDR to the row selection circuit 460, and may provide the received column address COL_ADDR to the column decoder 470.

The bank control logic 430 may generate bank control signals in response to the bank address BANK_ADDR. One of the bank row selection circuits 460a, . . . , 460h corresponding to the bank address BANK_ADDR may be activated in response to the bank control signals, and one of the bank column decoders 470a, . . . , 470h corresponding to the bank address BANK_ADDR may be activated in response to the bank control signals.

The row address ROW_ADDR from the address register 420 may be applied to the bank row selection circuits 460a, . . . , 460h. The activated one of the bank row selection circuits 460a, . . . , 460h may decode the row address ROW_ADDR, and may activate a wordline corresponding to the row address ROW_ADDR. For example, the activated bank row selection circuit 460 may apply a wordline driving voltage to the wordline corresponding to the row address ROW_ADDR.

The column decoder 470 may include a column address latch. The column address latch may receive the column address COL_ADDR from the address register 420, and may temporarily store the received column address COL_ADDR. In some example embodiments, in a burst mode, the column address latch may generate column addresses that increment from the received column address COL_ADDR. The column address latch may apply the temporarily stored or generated column address to the bank column decoders 470a, . . . , 470h.

The activated one of the bank column decoders 470a, . . . , 470h may decode the column address COL_ADDR, and may control the I/O gating circuit 490 in order to output data corresponding to the column address COL_ADDR.

The I/O gating circuit 490 may include a circuitry for gating input-output data. The I/O gating circuit 490 may further include read data latches for storing data that is output from the bank arrays 480a, . . . , 480h, and write drivers for writing data to the bank arrays 480a, . . . , 480h.

Data to be read from one bank array of the bank arrays 480a, . . . , 480h may be sensed by one of the bank sense amplifiers 485a, . . . , 485h coupled to the one bank array from which the data is to be read, and may be stored in the read data latches. The data stored in the read data latches may be provided to the memory controller 50 via the data I/O buffer 495. Data DQ to be written in one bank array of the bank arrays 480a, . . . , 480h may be provided to the data I/O buffer 495 from the memory controller 50. The write driver may write the data DQ in one bank array of the bank arrays 480a, . . . , 480h.

The command control logic 410 may control operations of the semiconductor memory device 400. For example, the command control logic 410 may generate control signals for the semiconductor memory device 400 in order to perform a write operation, a read operation, or a refresh operation. The command control logic 410 may generate internal command signals such as an active signal IACT, a precharge signal IPRE, a refresh signal IREF, a read signal IRD, a write signal IWR, etc., based on commands CMD transferred from the memory controller 50 in FIG. 3. The command control logic 410 may include a command decoder 411 that decodes the commands CMD received from the memory controller 50 and a mode register 412 that sets an operation mode of the semiconductor memory device 400.

Although FIG. 15 illustrates the command control logic 410 and the address register 420 as being distinct from each other, the command control logic 410 and the address register 420 may be implemented as a single integrated circuit. In addition, although FIG. 15 illustrates the command CMD and the address ADDR being provided as distinct signals, the command CMD and the address ADDR may be provided as a combined signal, e.g., as specified by DDR5, HBM and LPDDR5 standards.

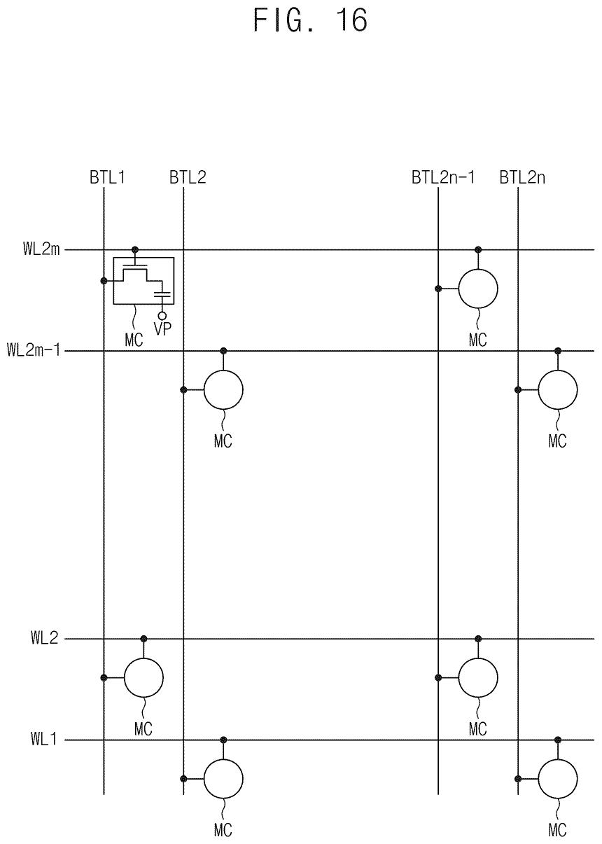

FIG. 16 is a diagram illustrating an example embodiment of a bank array included in a semiconductor memory device according to example embodiments.

Referring to FIG. 16, a bank array 310 includes a plurality of wordlines WL1˜WL2m (where m is a natural number greater than two), a plurality of bitlines BTL1˜BTL2n (where n is a natural number greater than two), and a plurality of memory cells MCs disposed near intersections between the wordlines WL1˜WL2m and the bitlines BTL1˜BTL2n. In some example embodiments, each of the plurality of memory cells MC may include a DRAM cell structure as illustrated in FIG. 16. The memory cell MC may include a cell capacitor connected to the plate voltage VP and a cell transistor connected between each bitline and the cell capacitor, and the gate electrode of the cell transistor is connected to each wordline. The plurality of wordlines WL1˜WL2m to which the plurality of memory cells MC are connected may be referred to as rows of the bank array 310 and the plurality of bitlines BL1˜BL3n to which the plurality of memory cells MC are connected may be referred to as columns of the bank array 310.

The semiconductor chips described above may be memory semiconductor chips on which semiconductor memory devices are integrated. The semiconductor memory devices integrated on the semiconductor chips may be DRAM devices as described with reference to FIGS. 15 and 16, but example embodiments are not limited to any particular type of memory.

Example embodiments are not limited to a specific number of semiconductor chips stacked together, and the number of semiconductor chips included in a semiconductor package may be varied, such as two, four, eight, sixteen, or the like.

Semiconductor memory devices have various configurations and operating characteristics depending on their specifications, and different semiconductor memory devices have different temperature operating conditions.

For example, in volatile memory devices such as DRAM, the refresh period or refresh window tREFW indicates the amount of time each memory cell must be refreshed again, or the total time required to refresh all wordlines once, since the refresh operation is performed on a per-wordline basis.

For example, if the refresh window tREFW is A ms (milliseconds) and the number of refresh commands sent from the memory controller within the refresh window tREFW is B, the average refresh interval time tREFI between adjacent refresh commands is (A×1000)/B us (microseconds).

In this case, the memory controller must issue a refresh command every average refresh interval time tREFI and the semiconductor memory device perform a refresh operation within the refresh cycle time tRFC after issuing the refresh command.

During the refresh cycle time tRFC, other commands and accesses to the memory device are prohibited, and the resulting time loss corresponding to the refresh cycle time tRFC degrades the performance of the memory system.

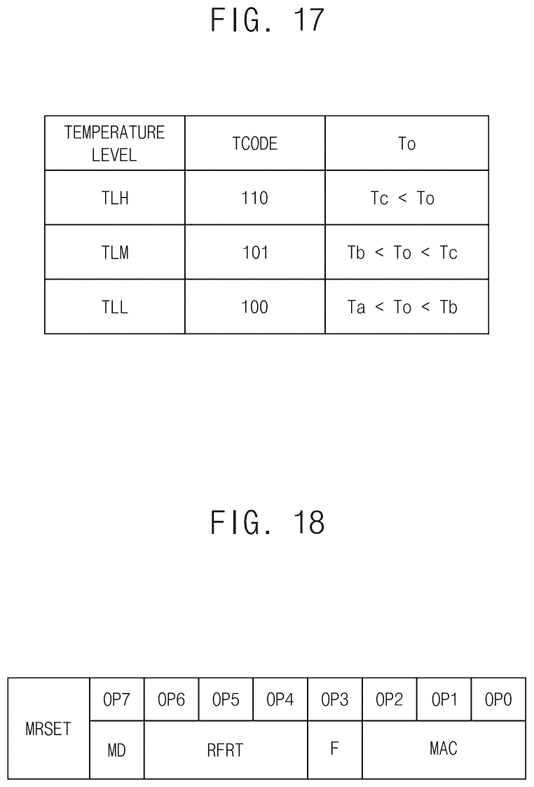

FIG. 17 is a diagram illustrating an example embodiment of setting a temperature level in a semiconductor memory device according to example embodiments. FIG. 17 is only an example set of temperature levels, and example embodiments are not limited to the set of temperature levels in FIG. 17.

Referring to FIG. 17, temperature levels may be set by dividing the entire range of the operating temperature To of the memory cell array or memory device into a plurality of ranges. For example, the operating temperature To may be set to a high temperature level TLH when the range is above Tc, a medium temperature level TLM when the range is from Tb to Tc, and a low temperature level TLL when the range is from Ta to Tb.

As the operating temperature To decreases, the amount of leakage of charge stored in the memory cells decreases, so the refresh window tREFW may increase and the average refresh interval time tREFI may increase. For example, the refresh window tREFW may be N ms at the high temperature level TLH, 2 N ms at the medium temperature level TLM, and 4 N ms at the low temperature level TLL. Accordingly, the average refresh interval time tREFI may be M us at the high temperature level TLH, 2 M us at the medium temperature level TLM, and 4 M us at the low temperature level TLL.

As such, the temperature levels may be represented by digital values of a temperature code TCODE. As described above, each temperature sensor in the temperature sensing circuit may generate the sensing voltage corresponding to the operating temperature To of the memory cell array, i.e., the ambient temperature, and output the sensing voltage as temperature information in analog form, and the conversion circuit may convert the sensing voltage into the temperature code TCODE and provide the temperature code TCODE to the memory controller.

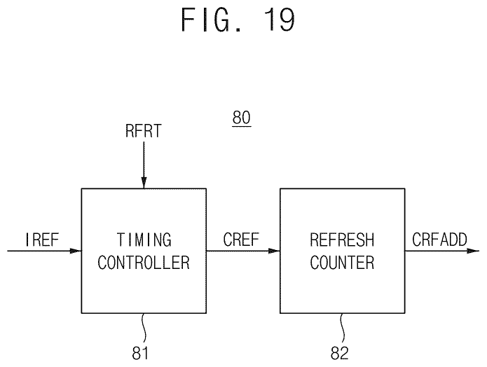

FIG. 18 is a diagram illustrating an example embodiment of register information in a semiconductor memory device according to example embodiments.

For example, one mode register included in the mode registers 412 of FIG. 15 may have a mode register set MRSET as shown in FIG. 18. The values of the operands OP0 through OP7 may include mode information MD, refresh rate information RFRT, flag information F, and maximum active count information MAC.

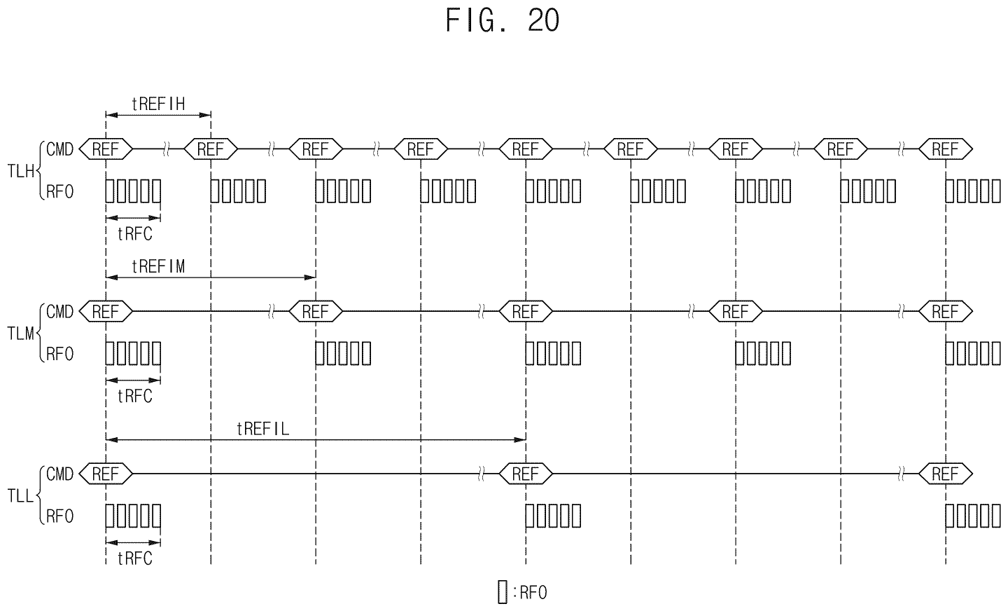

The mode information MD may indicate whether the operating mode of the memory system is a fixed refresh control mode or a variable refresh control mode. For example, a value of ‘0’ for the mode information MD may indicate the fixed refresh control mode and a value of ‘1’ may indicate the variable refresh control mode. The fixed refresh control mode and the variable refresh control mode will be described below with reference to FIGS. 20 through 22.

Refresh rate information RFRT may represent information regarding the number of executions of a refresh operation executed during the refresh cycle time tRFC.

The memory controller may determine and provide the refresh rate information RFRT to the semiconductor memory device based on the operating temperature To of the memory cell array and/or the criticality of the data stored in the memory cell array. For example, a larger value of the refresh rate information RFRT may indicate a larger number of required executions of the refresh operation.

The flag information F indicates whether the maximum active count information MAC is valid, wherein the maximum active count information MAC indicates the maximum number of active operations allowed within the refresh window REFW before a row (i.e., wordline) is refreshed.

The memory controller may generate the refresh rate information RFRT based on the above temperature information or temperature code TCODE received from the semiconductor memory device and transfer the mode information MD and the refresh rate information RFRT to the semiconductor memory device via a mode register set (MRS) command.

The semiconductor memory device may store the mode information MD and the refresh rate information RFRT received from the memory controller in one mode register included in the mode registers 412 of FIG. 15. The refresh controller of the semiconductor memory device may vary the frequency of the refresh operation based on the refresh rate information RFRT stored in the mode register in a variable refresh control mode.

FIG. 19 is a block diagram illustrating an example embodiment of a refresh controller included in the semiconductor memory device of FIG. 15.

Referring to FIG. 19, a refresh controller 80 may include a timing controller 81 and a refresh counter 82.

The timing controller 81 may generate a refresh signal IREF indicating when a refresh command REF is received and a counter refresh signal CREF indicating the timing of a refresh operation based on refresh rate information RFRT.

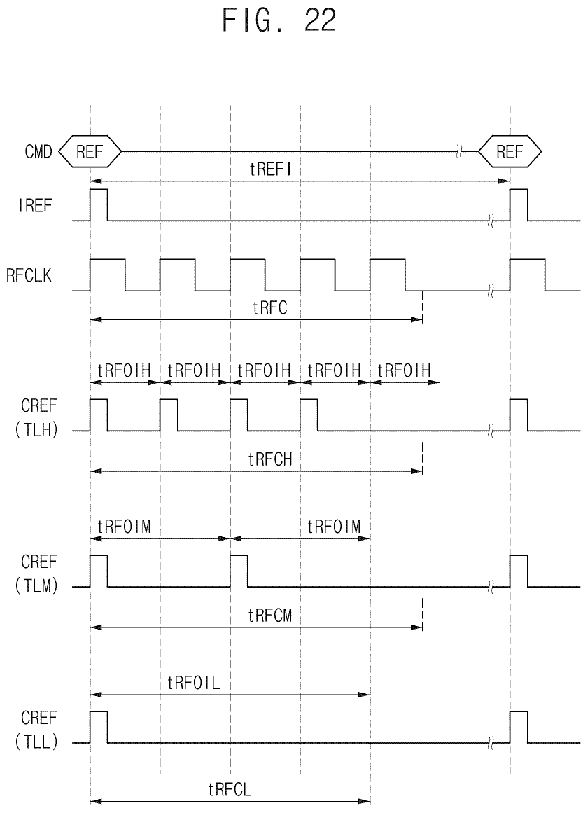

As will be described below with reference to FIG. 22, the timing controller 81 may selectively enable the counter refresh signal CREF.

In an example embodiment, the timing controller 81 may be included in the refresh controller 80 as shown in FIG. 19. In other example embodiments, the timing controller 81 may be omitted, and the counter refresh signal CREF may be provided from other control logic within the semiconductor memory device.

The refresh counter 82 generates a counter refresh address signal CRFADD indicating a sequentially changing address synchronous to the counter refresh signal CREF.

For example, the refresh counter 82 may increment the value of the counter refresh address signal CRFADD by one each time the counter refresh signal CREF is activated. In this way, by incrementing the value of the counter refresh address signal CRFADD by one, the wordlines for the refresh operation may be sequentially selected one by one.

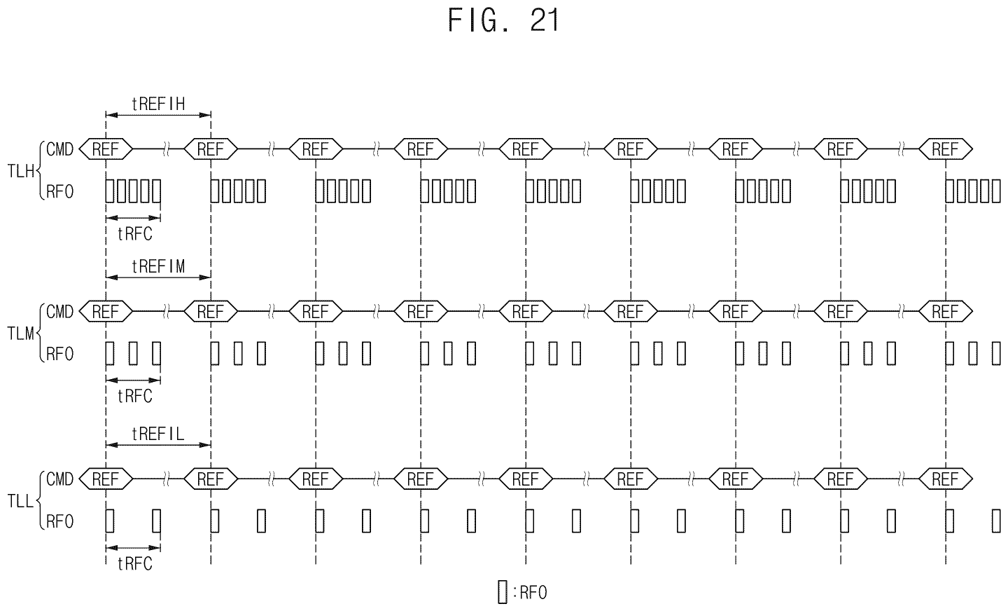

Hereinafter, referring now to FIGS. 20 and 21, a fixed refresh control mode and a variable refresh control mode according to example embodiments will be described. As described above, the memory controller may transfer refresh commands REF to the semiconductor memory device via a command signal CMD, and the semiconductor memory device may perform refresh operations RFO during a refresh cycle time tRFC in which no other commands are allowed to occur from the time each refresh command REF is received from the memory controller.

For convenience of description, example embodiments of FIGS. 20 and 21 will be described based on the example of the temperature setting of FIG. 17. The numbers referenced for the number of refresh operations RFO shown in FIGS. 20 and 21 and the times tREFIH, TREFIM, TREFIL and tRFC are for illustrative and explanatory purposes only and are not intended to limit the example embodiments.

FIG. 20 is a timing diagram illustrating an example embodiment of a fixed refresh control mode of a semiconductor memory device according to example embodiments.

Referring to FIG. 20, in the fixed refresh control mode, the memory controller may increase the average refresh interval time tREFIM at the medium temperature level TLM rather than the average refresh interval time tREFIH at the high temperature level TLH, and may increase the average refresh interval time tREFIL at the low temperature level TLL rather than the average refresh interval time tREFIM at the medium temperature level TLM.

For example, the aforementioned refresh window tREFW may be 16 ms at the high temperature level TLH, 32 ms at the medium temperature level TLM, and 64 ms at the low temperature level TLL.

Further, the average refresh interval time tREFI may be 3.9 us at the high temperature level TLH, 7.8 us at the medium temperature level TLM, and 17.6 us at the low temperature level TLL. As a result, the number of refresh commands REF contained within the refresh window tREFW at the high temperature level TLH, the medium temperature level TLM, and the low temperature level (TLL) may be the same.

As such, the memory controller may increase the average refresh interval time at the second temperature level where the operating temperature of the memory cell array is relatively low compared to the average refresh interval time at the first temperature level where the operating temperature of the memory cell array is relatively high in the fixed refresh control mode.

The refresh controller of the semiconductor memory device may maintain the number of unit executions of refresh operations RFO executed during the refresh cycle time tRFC in the fixed refresh control mode regardless of the operating temperature of the memory cell array. For example, as shown in FIG. 19, the number of unit executions at the high temperature level TLH, the medium temperature level TLM, and the low temperature level TLL may be fixed as five.

FIG. 21 is a timing diagram illustrating an example embodiment of a variable refresh control mode of a semiconductor memory device according to example embodiments.

Referring to FIG. 21, in the variable refresh control mode, the memory controller may maintain the average refresh interval time tREFIH at the high temperature level TLH, the average refresh interval time tREFIM at the medium temperature level TLM, and the average refresh interval time tREFIL at the low temperature level TLL to be the same.

For example, the aforementioned refresh window tREFW may be 16 ms at the high temperature level TLH, 32 ms at the medium temperature level TLM, and 64 ms at the low temperature level TLL. On the other hand, the average refresh interval times tREFIH, tREFIM, and tREFIL at the high temperature level TLH, the medium temperature level TLM, and the low temperature level TLL may all remain the same at 3.9 us. In this case, the number of refresh commands included within the refresh window tREFW may be P at the high temperature level TLH, 2 P at the medium temperature level TLM, and 4 P at the low temperature level TLL.

As such, in the variable refresh control mode, the memory controller may maintain the same average refresh interval time at the first temperature level, where the operating temperature of the memory cell array is relatively high, and the same average refresh interval time at the second temperature level, where the operating temperature of the memory cell array is relatively low.

Compared to the fixed refresh control mode of FIG. 20, in the variable refresh control mode of FIG. 21, the memory controller may send a greater number of refresh commands REF than the number of the required refresh commands REF as the operating temperature level is lowered.

In an example embodiment, the refresh controller may reduce the number of unit executions at a second temperature level having a relatively lower operating temperature than the number of unit executions at a first temperature level in the variable refresh control mode.

For example, as shown in FIG. 21, the number of unit executions may be reduced for temperature levels corresponding to lower operating temperatures, such as the number of unit executions at the high temperature level TLH is five, the number of unit executions at the medium temperature level TLM is three, and the number of unit executions at the low temperature level TLL is two.

FIG. 22 is a timing diagram illustrating example embodiments of a variable refresh control mode of a semiconductor memory device according to example embodiments.

For convenience of illustration, the operation corresponding to one average refresh interval time tREFI between two refresh commands REF is shown in FIG. 22.

Referring to FIGS. 19, 21 and 22, the timing controller 81 may generate a refresh clock signal RFCLK in response to the refresh signal IREF. The refresh clock signal RFCLK may be toggled by a number of refresh operations that may be performed within the refresh cycle time tRFC.

For each of the cases of the high temperature level TLH, the medium temperature level TLM, and the low temperature level TLL, the timing controller 81 may generate a counter refresh signal CREF synchronous to the refresh clock signal RFCLK to indicate the timing of the refresh operation.

The counter refresh signal CREF may be toggled by a number of unit executions for each of the cases of the high temperature level TLH, the medium temperature level TLM, and the low temperature level TLL.

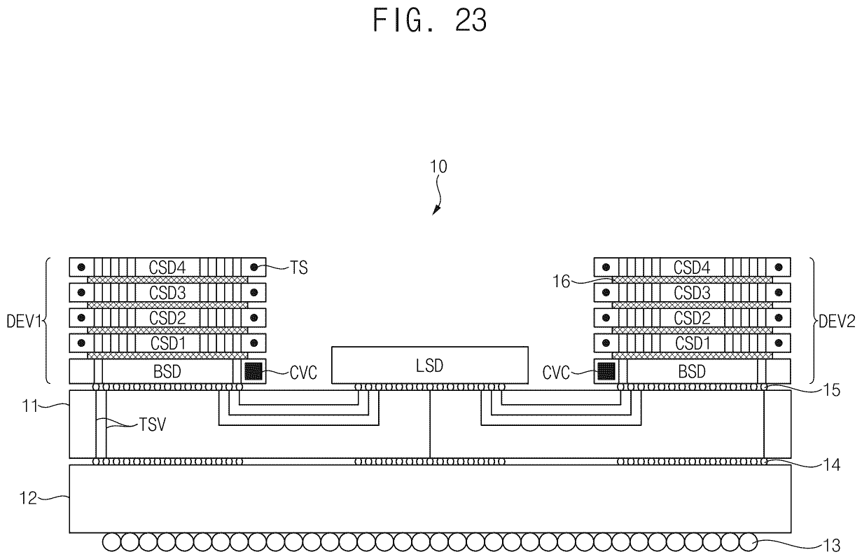

FIG. 23 is a diagram illustrating a memory system according to example embodiments.

FIG. 23 illustrates an example multi-chip package 10 in which a per-channel thermal management technique may be implemented. In the example shown in FIG. 23, the multi-chip package 10 includes a package substrate 12 and an interposer 11 mounted on the package substrate 12. The interposer 11 may be electrically coupled to the package substrate 12 via C4 bumps 14, pads, or any other conductive contact. The package substrate 12 may be connected to an external device via contact means 13 formed on its underside, such as balls in a ball grid array (BGA). The interposer 11 includes a metal layer forming conductive traces through silicon via (TSV) and/or other conductive contacts or interconnections. Conductive interconnects within the interposer provide connections for devices mounted on the interposer 11 and/or conductive contacts on the package substrate 12. For example, the interposer 11 may include interconnects for connecting logic die LSD to memory devices, such as HBM stacks DEV1 and DEV2. The interposer 11 may include an active device (e.g., a die that includes transistors or other active components) or a passive device (e.g., a die that does not include active components). In an example, the HBM stacks DEV1 and DEV2 are connected to the logic die LSD via a bridge die (e.g., an embedded multi-die interconnect bridge (EMIB)) or via another technique for combining chips in a multi-chip package. Although two HBM stacks DEV1 and DEV2 are shown, the multi-chip package 10 may include a single HBM stack, three or more HBM stacks.

The multi-chip package includes the logic die LSD mounted on the interposer 11. The logic die LSD may be or include a system on a chip (SoC), a field programmable gate array (FPGA), a central processing unit (CPU), an accelerator, a graphics processing unit (GPU), or other logic die. The logic die (LSD) is coupled to the HBM stacks DEV1 and DEV2 via an interconnection of the interposer 11, an EMIB, or other interconnection between the logic die LSD and the HBM stacks DEV1 and DEV2. The HBM stacks DEV1 and DEV2 may be the same as or similar to the stacked semiconductor device described with reference to FIGS. 1 through 12. As illustrated in FIG. 23, the HBM stacks DEV1 and DEV2 includes a base semiconductor die BSD and a plurality of core semiconductor dies CSD1, CSD2, CSD3, and CSD4 that are stacked in a vertical direction, and the base semiconductor die BSD and the plurality of core semiconductor dies CSD1, CSD2, CSD3, and CSD4 are electrically connected to each other through a plurality of vertical conductive paths including through silicon vias TSV. The HBM stacks DEV1 and DEV2 may be internally and externally connected through contacts 15 and 16, for example, micro bumps. Temperature sensors TS are interspersed and arranged in the plurality of core semiconductor dies CSD1, CSD2, CSD3, and CSD4, and a conversion circuit CVC is arranged in the base semiconductor die BSD. According to example embodiments, sensing voltages generated by the temperature sensors TS may be transferred to the conversion circuit CVC by a time-division method through at least one vertical conductive path.

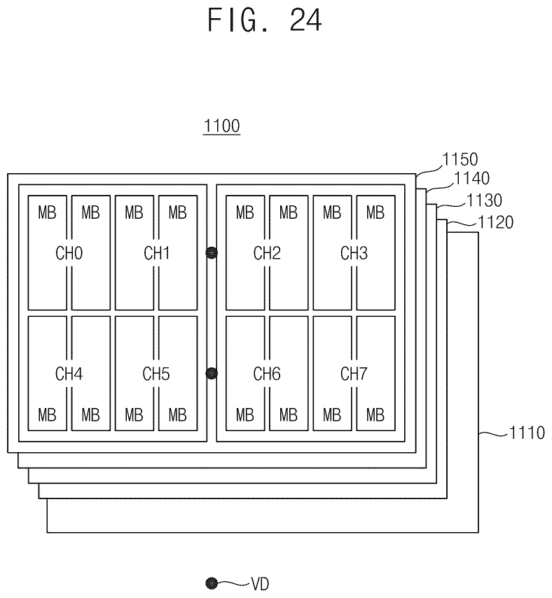

FIGS. 24, 25 and 26 are diagrams illustrating stacked semiconductor devices according to example embodiments.

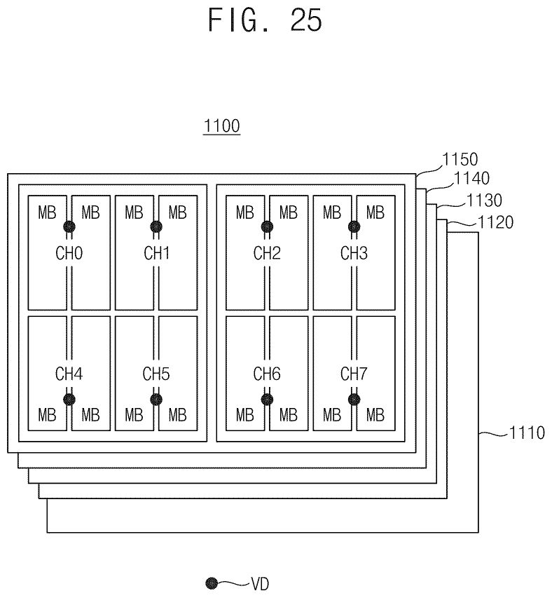

FIGS. 24, 25 and 26 illustrate example structures of a high bandwidth memory. Referring to FIGS. 24 and 25, a high bandwidth memory (HBM) 1100 may include a structure in which a plurality of DRAM semiconductor dies 1120, 1130, 1140 and 1150 are stacked. The plurality of DRAM semiconductor dies 1120, 1130, 1140 and 1150 correspond to the core semiconductor dies described above.

The high bandwidth memory may be optimized for high bandwidth operation of the stacked structure through a plurality of independent interfaces called channels. According to the HBM standard, each DRAM stack may support a variety of channels.

FIGS. 24 and 25 illustrate an example in which four DRAM semiconductor dies are stacked, but the example embodiments are not limited thereto. Each semiconductor die may provide additional capacity and additional channels to the stacked structure. Each channel provides access to an independent set of DRAM banks. Requests from one channel do not access data attached to another channel. The channels are independently clocked and do not need to be synchronized with each other. FIGS. 24 and 25 illustrate an example in which the memory banks MB of each DRAM semiconductor die are grouped into eight independent channels CH0-CH7, but example embodiments are not limited thereto. The high bandwidth memory 1100 may include a buffer die or interface die 1110 located at the bottom of the stacked structure and providing signal redistribution and other functions. Functions typically implemented in the DRAM semiconductor dies 1120, 1130, 1140 and 1150 may be implemented in the interface die 1110. The interface die 1110 corresponds to the base semiconductor die described above. According to example embodiments, the high bandwidth memory 1100 may include temperature sensing circuits included in the plurality of DRAM semiconductor dies 1120, 1130, 1140 and 1150 and a conversion circuit included in the base semiconductor die 1110.

FIGS. 24 and 25 illustrate example embodiments of arrangements of a plurality of voltage devices VD included in the temperature sensing circuit. As described above, the plurality of voltage devices VD are distributed within each core semiconductor die, i.e., each DRAM semiconductor die, and generate temperature voltages that vary according to their respective operating temperatures.

In an example embodiment, as illustrated in FIG. 24, each DRAM semiconductor die may include one voltage device VD corresponding to the upper channels CH0 through CH3 and another voltage device VD corresponding to the lower channels CH4 through CH7. In this case, the high bandwidth memory 1100 provides temperature information for the upper channels CH0 through CH3 and the lower channels CH4 through CH7 to the memory controller, and the memory controller may independently control the operation of the upper channels CH0 through CH3 and the lower channels CH4 through to CH7. In an example embodiment, as illustrated in FIG. 25, each DRAM semiconductor die may include voltage devices VD corresponding to the channels CH0 through CH7, for example, eight voltage devices VD corresponding to eight channels CH0 through CH7. In this case, the high bandwidth memory 1100 provides temperature information for each channel to the memory controller, and the memory controller may independently control the operation of the channels.

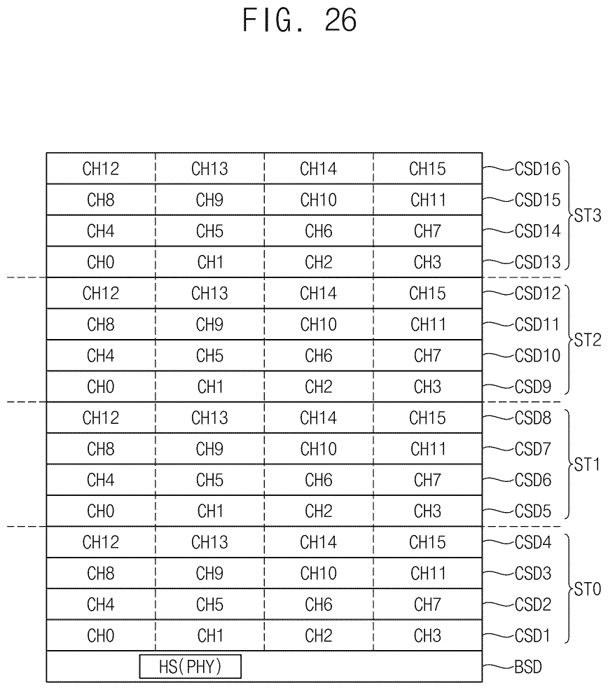

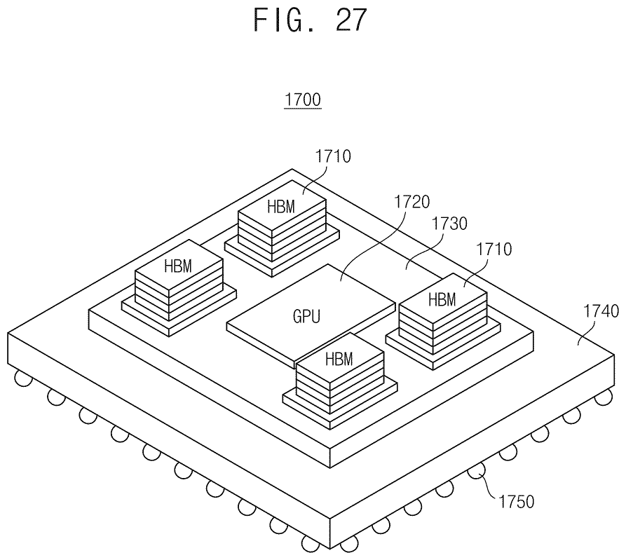

Referring to FIG. 26, a plurality of core semiconductor dies CSD1 through CSD16 included in a stacked semiconductor device may be grouped into a plurality of sub-stacks ST0 through ST3. Each of the plurality of sub-stacks ST0 through ST3 may include a plurality of channels CH0 through CH15.

There are various heat sources in the stacked semiconductor device, and among the heat sources, there is a hot spot HS that has a particularly large amount of heat generation. For example, the hot spot HS may include an interface circuit PHY included in the base semiconductor die BSD. The closer to the hot spot HS, the higher the operating temperature, and the farther away, the lower the operating temperature. In other words, even for memory banks belonging to the same channel, the operating temperature of the lowest sub-stack ST0 may be higher than the operating temperature of the uppermost sub-stack ST3.

According to example embodiments, by efficiently providing temperature information of each core semiconductor die, it is possible to actively cope with various temperature distributions of the stacked semiconductor device.

FIG. 27 is a structural diagram illustrating an example embodiment of a semiconductor package including a semiconductor memory device according to example embodiments.

Referring to FIG. 27, a semiconductor package 1700 may include one or more stacked memory devices 1710 and a GPU 1720. The stacked memory devices 1710 and the GPU 1720 may be mounted on an interposer 1730, and the interposer 1730 on which the stacked memory devices 1710 and the GPU 1720 are mounted may be mounted on a package substrate 1740. The GPU 1720 may perform substantially the same function as the aforementioned memory controller or may include a memory controller therein. The GPU 1720 may store data generated or used during a graphics processing process in one or more stacked memory devices 1710. The stacked memory device 1710 may be implemented in various forms, and according to an example embodiment, the stacked memory device 1710 may be a semiconductor memory device in the form of an HBM in which a plurality of layers are stacked. Accordingly, the stacked memory device 1710 may include a buffer semiconductor die and a plurality of core semiconductor dies. According to example embodiments, the stacked memory device 1710 may have a configuration for providing temperature information as described above. By arranging a temperature sensing circuit in each core semiconductor die and arranging a conversion circuit common to a plurality of core semiconductor dies in a base semiconductor die, the design margin of the core semiconductor die may be optimized while efficiently providing temperature information of the stacked semiconductor device.

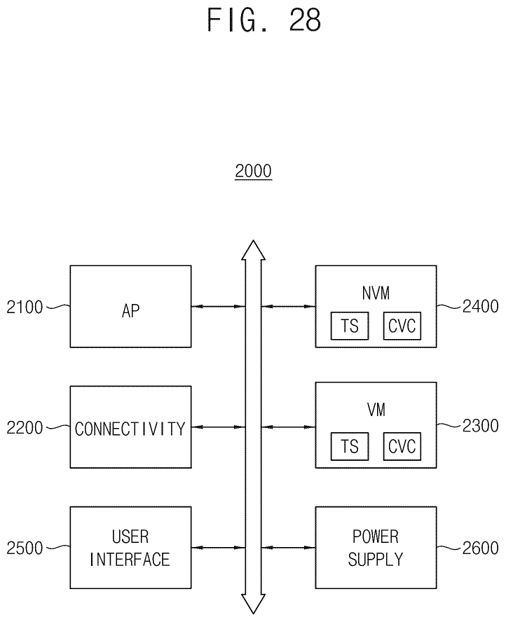

FIG. 28 is a block diagram illustrating a mobile system including a semiconductor memory device according to example embodiments.

Referring to FIG. 28, a mobile system 2000 includes an application processor 2100, a connectivity unit 2200, a semiconductor memory device 2300, a nonvolatile semiconductor memory device 2400, a user interface 2500, and a power supply 2600. According to an example embodiment, the mobile system 2000 may be any mobile system such as a mobile phone, a smart phone, a personal digital assistant (PDA), a portable multimedia player (PMP), a digital camera, a music player, a portable game console, a navigation system, etc.

The application processor 2100 may execute applications that provide an Internet browser, a game, a video, etc. The communication unit 2200 may perform wireless or wired communication with an external device.

The semiconductor memory device 2300 may store data processed by the application processor 2100 or operate as a working memory.

The nonvolatile semiconductor memory device 2400 may store a boot image for booting the mobile system 2000. The user interface 2500 may include one or more input devices such as a keypad, a touch screen, and/or one or more output devices such as a speaker, a display device.

The power supply 2600 may supply an operating voltage of the mobile system 1200.

According to example embodiments, the semiconductor memory device 2300 and/or the nonvolatile semiconductor memory device 2400 may have a configuration for providing temperature information as described above. Each core semiconductor die may include a temperature sensing circuit in which temperature sensors TS are distributed, and the base semiconductor die may include a conversion circuit CVC common to a plurality of core semiconductor dies. Therefore, temperature information of a stacked semiconductor device may be efficiently provided while optimizing the design margin of the core semiconductor die.

As described above, the stacked semiconductor device according to example embodiments may efficiently provide temperature information of the stacked semiconductor device while optimizing the design margin of the core semiconductor die by disposing temperature sensing circuit in each core semiconductor die and the conversion circuit common to the plurality of core semiconductor die in the base semiconductor die.

Furthermore, the stacked semiconductor device according to example embodiments may efficiently provide temperature information of the stacked semiconductor device without increasing the load of the signal path by transferring the sensing voltages of the plurality of core semiconductor dies from the plurality of core semiconductor dies to the base semiconductor die using a single vertical conductive path.

The inventive concept may be applied to any electronic devices and systems. For example, the inventive concept may be applied to systems such as a memory card, a solid state drive (SSD), an embedded multimedia card (eMMC), a universal flash storage (UFS), a mobile phone, a smart phone, a personal digital assistant (PDA), a portable multimedia player (PMP), a digital camera, a camcorder, a personal computer (PC), a server computer, a workstation, a laptop computer, a digital TV, a set-top box, a portable game console, a navigation system, a wearable device, an internet of things (IoT) device, an internet of everything (IoE) device, an e-book, a virtual reality (VR) device, an augmented reality (AR) device, a server system, an automotive driving system, etc.

The foregoing is illustrative of example embodiments and is not to be construed as limiting thereof. Although a few example embodiments have been described, those skilled in the art will readily appreciate that many modifications are possible in the example embodiments without materially departing from the present inventive concept.

What is claimed is:

1. A stacked semiconductor device comprising:
a base semiconductor die comprising a conversion circuit;
a plurality of core semiconductor dies that is stacked on the base semiconductor die in a vertical direction and comprises a plurality of temperature sensing circuits, respectively; and
a plurality of vertical conductive paths electrically connecting the base semiconductor die and the plurality of core semiconductor dies, through silicon vias provided in the plurality of vertical conductive paths in the vertical direction,
wherein the plurality of temperature sensing circuits is configured to generate sensing voltages that vary according to operating temperatures, and transfer the sensing voltages to the conversion circuit through a first vertical conductive path among the plurality of vertical conductive paths, and
wherein the conversion circuit is configured to convert the sensing voltages into a temperature code.

2. The stacked semiconductor device of claim 1, wherein the conversion circuit is configured to convert the sensing voltages in analog form into the temperature code in digital form.

3. The stacked semiconductor device of claim 1, wherein a temperature sensing circuit of the plurality of temperature sensing circuits is configured to sequentially transfer the sensing voltages corresponding to the plurality of core semiconductor die to the conversion circuit through the first vertical conductive path.

4. The stacked semiconductor device of claim 1, wherein the plurality of temperature sensing circuits is further configured to transfer the sensing voltages corresponding to the plurality of core semiconductor die to the conversion circuit sequentially through the first vertical conductive path during a plurality of sensing intervals.

5. The stacked semiconductor device of claim 4, wherein the conversion circuit comprises:
a base timing controller configured to generate a base timing control signal representing the plurality of sensing intervals and transfer the base timing control signal to the plurality of temperature sensing circuits.

6. The stacked semiconductor device of claim 5, wherein the conversion circuit is further configured to transfer the base timing control signal to the plurality of temperature sensing circuits through a third vertical conductive path of the plurality of vertical conductive paths.

7. The stacked semiconductor device of claim 5, wherein a temperature sensing circuit of the plurality of temperature sensing circuits comprises:
a core timing controller configured to generate output timing control signals that are sequentially activated based on the base timing control signal during a sensing interval of the plurality of sensing intervals, and
wherein the temperature sensing circuit is configured to sequentially transfer the sensing voltages to the conversion circuit through the first vertical conductive path based on the output timing control signals during the sensing interval.

8. The stacked semiconductor device of claim 1, wherein the conversion circuit comprises:
a base reference voltage generator configured to generate a base reference voltage having a constant voltage level regardless of temperature; and
an analog-to-digital converter configured to generate digital values of the temperature code by comparing the base reference voltage and the sensing voltages corresponding to the plurality of core semiconductor dies.

9. The stacked semiconductor device of claim 1, wherein a temperature sensing circuit of the plurality of temperature sensing circuits comprises:
a core reference voltage generator configured to generate a core reference voltage having a constant voltage level regardless of temperature.

10. The stacked semiconductor device of claim 9, wherein the plurality of temperature sensing circuits is configured to sequentially transfer core reference voltages corresponding to the plurality of core semiconductor dies to the conversion circuit through a second vertical conductive path of the plurality of vertical conductive paths during a plurality of sensing intervals.

11. The stacked semiconductor device of claim 10, wherein the conversion circuit comprises:
an analog-to-digital converter configured to generate digital values of the temperature code by comparing the core reference voltage of the core reference voltages and the sensing voltages corresponding to the core semiconductor die, respectively.

12. The stacked semiconductor device of claim 10, wherein the conversion circuit comprises:
a base timing controller configured to generate a base timing control signal representing the plurality of sensing intervals and transfer the base timing control signal to the plurality of temperature sensing circuits, and
wherein the temperature sensing circuit comprises:
a core timing controller configured to generate a core timing control signal representing a sensing interval of the plurality of sensing intervals based on the base timing control signal.

13. The stacked semiconductor device of claim 12, wherein the plurality of temperature sensing circuits is configured to sequentially transfer the core reference voltages corresponding to the plurality of core semiconductor dies to the conversion circuit through the second vertical conductive path based on a plurality of core timing control signals corresponding to the plurality of core semiconductor dies, respectively.

14. The stacked semiconductor device of claim 1, wherein a temperature sensing circuit of the plurality of temperature sensing circuits comprises:
a plurality of voltage devices on or within a core semiconductor die of the plurality of core semiconductor dies, the plurality of voltage devices being configured to generate temperature voltages that vary according to the operating temperatures;
a plurality of voltage adjustment circuits configured to convert the temperature voltages to the sensing voltages;
a core timing controller configured to generate output timing control signals that are sequentially activated; and
a multiplexer configured to sequentially select the sensing voltages based on the output timing control signals and provide the selected sensing voltages.

15. The stacked semiconductor device of claim 1, wherein the conversion circuit comprises:
a base timing controller configured to generate latch timing control signals that are sequentially activated;
an analog-to-digital converter configured to sequentially select and convert the sensing voltages based on the latch timing control signals and generate digital values of the temperature code; and
a register configured to sequentially store the digital values of the temperature code based on the latch timing control signals.

16. A stacked semiconductor device comprising:
a base semiconductor die comprising a conversion circuit;
a first core semiconductor die on the base semiconductor die in a vertical direction, and the first core semiconductor die comprising a first temperature sensing circuit;
a second core semiconductor die on the first core semiconductor die in the vertical direction, the second core semiconductor die comprising a second temperature sensing circuit; and
a plurality of vertical conductive paths electrically connecting the base semiconductor die, the first core semiconductor die, and the second core semiconductor die, through silicon vias provided in the plurality of vertical conductive paths in the vertical direction,
wherein the first temperature sensing circuit is configured to generate first sensing voltages that vary according to operating temperatures of the first core semiconductor die, and transfer the first sensing voltages to the conversion circuit through a first vertical conductive path among the plurality of vertical conductive paths,
wherein the second temperature sensing circuit is configured to generate second sensing voltages that vary according to operating temperatures of the second core semiconductor die, and transfer the second sensing voltages to the conversion circuit through the first vertical conductive path, and
wherein the conversion circuit is configured to convert the first sensing voltages and the second sensing voltages into a temperature code.

17. The stacked semiconductor device of claim 16, wherein the first temperature sensing circuit is further configured to sequentially transfer the first sensing voltages through the first vertical conductive path during a first sensing interval, and
wherein the second temperature sensing circuit is further configured to sequentially transfer the second sensing voltages through the first vertical conductive path during a second sensing interval different from the first sensing interval.

18. The stacked semiconductor device of claim 17, wherein the conversion circuit comprises:
a base timing controller configured to generate a base timing control signal representing the first sensing interval and the second sensing interval and transfer the base timing control signal to the first temperature sensing circuit and the second temperature sensing circuit,
wherein the first temperature sensing circuit comprises:
a first core timing controller configured to generate first output timing control signals that are sequentially activated based on the base timing control signal during the first sensing interval, and
wherein the second temperature sensing circuit comprises:
a second core timing controller configured to generate second output timing control signals that are sequentially activated based on the base timing control signal during the second sensing interval.

19. The stacked semiconductor device of claim 16, wherein the first temperature sensing circuit comprises:
a first core reference voltage generator configured to generate a first core reference voltage having a constant voltage level regardless of temperature, and transfer the first core reference voltage to the conversion circuit through a second vertical conductive path of the plurality of vertical conductive paths, and
wherein the second temperature sensing circuit comprises:
a second core reference voltage generator configured to generate a second core reference voltage having a constant voltage level regardless of temperature, and transfer the second core reference voltage to the conversion circuit through the second vertical conductive path.

20. A stacked semiconductor device comprising:
a base semiconductor die comprising a conversion circuit;
a first core semiconductor die on the base semiconductor die in a vertical direction, and the first core semiconductor die comprising:
a first temperature sensing circuit configured to generate first sensing voltages that vary according to operating temperatures of the first core semiconductor die; and
a first core reference voltage generator configured to generate a first core reference voltage;
a second core semiconductor die on the first core semiconductor die in the vertical direction, the second core semiconductor die comprising:
a second temperature sensing circuit configured to generate second sensing voltages that vary according to operating temperatures of the second core semiconductor die; and
a second core reference voltage generator configured to generate a second core reference voltage; and
a plurality of vertical conductive paths electrically connecting the base semiconductor die, the first core semiconductor die, and the second core semiconductor die, through silicon vias provided in the plurality of vertical conductive paths in the vertical direction,
wherein the first sensing voltages and the second sensing voltages are transferred through a first vertical conductive path among the plurality of vertical conductive paths, and
wherein the first core reference voltage and the second core reference voltage are transferred through a second vertical conductive path among the plurality of vertical conductive paths.
